(19) United States
(12) Patent Application Publication
(10) Pub. No.: US 2026/0136519 A1
(43) Pub. Date: May 14, 2026

(54) STAGGERED-LAYER CELL AND METHOD OF MANUFACTURING STAGGERED-LAYER CELL

(71) Applicant: INSTITUTE OF MICROELECTRONICS, CHINESE ACADEMY OF SCIENCES, Beijing (CN)

(72) Inventors: Huaxiang YIN, Beijing (CN); Lei CAO, Beijing (CN); Qingzhu ZHANG, Beijing (CN); Jiaxin YAO, Beijing (CN)

(21) Appl. No.: 19/180,408

(22) Filed: Apr. 16, 2025

(30) Foreign Application Priority Data
Nov. 12, 2024 (CN) 202411610484.1

(51) Int. Cl. H10B 10/00

(52) U.S. Cl. CPC H10B 10/125

(57) ABSTRACT

The present disclosure provides a staggered-layer cell and a manufacturing method. The staggered-layer cell includes: first and second groups of field effect transistors on an upper surface of a substrate, each group being arranged in a first direction; an intermediate dielectric layer surrounding the substrate, the first and second groups of field effect transistors; a first staggered-layer contact hole connected to a gate stack of a pull transistor in the first group, extends in the intermediate dielectric layer to a lower surface of the substrate and passes through the substrate to be connected to a common layer of the second group, so as to form a staggered-layer structure with a second staggered-layer contact hole used to connect a gate stack of a pull transistor in the second group to a common layer of the first group, so that the first and second groups of field effect transistors are cross-coupled.

### CROSS REFERENCE TO RELATED APPLICATION

This application claims priority to Chinese Patent Application No. 202411610484.1, filed on Nov. 12, 2024, the entire content of which is incorporated herein in its entirety by reference.

### TECHNICAL FIELD

The present disclosure relates to the field of semiconductor technology, and in particular, to a staggered-layer cell and a method of manufacturing a staggered-layer cell.

### BACKGROUND

With the continuous development of manufacturing process nodes and key technologies of integrated circuits, NS-GAA FET (Nano-Sheet Gate-All-Around Field-Effect Transistor) will replace the existing Fin FET (Fin Field-Effect Transistor) technology at nodes less than or equal to 3 nm. Furthermore, three-dimensional stacked transistors, which include three-dimensional stacked integrated transistors, VFET (Vertical Field-Effect Transistor) and the like, will become the main technology route after the 1 nm node. The three-dimensional stacked integrated transistor is 3DS FET, which is also known as CFET (Complementary Field Effect Transistor).

The main process methods for implementing 3DS FET include two categories, where one is sequential integration, and the other is self-aligned monolithic integration. The former process method is simple, but is limited by performance and resources; the latter process method enables high integration and superior performance, but is complex and has various process technology challenges.

### SUMMARY

The present disclosure provides a staggered-layer cell and a method of manufacturing a staggered-layer cell.

According to an aspect of the present disclosure, a staggered-layer cell is provided, including: a first group of field effect transistors and a second group of field effect transistors on an upper surface of a substrate, where each of the first group of field effect transistors and the second group of field effect transistors is arranged in a first horizontal direction; and an intermediate dielectric layer surrounding the substrate, the first group of field effect transistors and the second group of field effect transistors. Each of the first group of field effect transistors and the second group of field effect transistors includes a transmission transistor and stacked pull transistors, the stacked pull transistors include a pull-down transistor and a pull-up transistor stacked in a vertical direction, and each of the transmission transistor, the pull-down transistor and the pull-up transistor includes: a channel layer; a source/drain layer connected to the channel layer on opposite sides of the channel layer in the first horizontal direction; and a gate stack that extends in a second horizontal direction intersecting the first horizontal direction and surrounds the channel layer. The pull-down transistor, the pull-up transistor and the transmission transistor in a same group are coupled to one another through a common layer. A first staggered-layer contact hole connected to the gate stack of the pull transistor in the first group of field effect transistors, extends in the intermediate dielectric layer to a lower surface of the substrate and passes through the substrate to be connected to the common layer of the second group of field effect transistors, so as to form a staggered-layer structure with a second staggered-layer contact hole used to connect the gate stack of the pull transistor in the second group of field effect transistors and the common layer of the first group of field effect transistors, so that the first group of field effect transistors and the second group of field effect transistors are cross-coupled with each other.

According to an embodiment of the present disclosure, the first group of field effect transistors and the second group of field effect transistors are arranged along the second horizontal direction, and a spacing space is arranged between the first group of field effect transistors and the second group of field effect transistors; the first staggered-layer contact hole extends towards the spacing space from the gate stack of the pull transistor in the first group of field effect transistors to the lower surface of the substrate, and passes through the substrate to be connected to the common layer in the second group of field effect transistors; and the second staggered-layer contact hole extends towards the spacing space from the gate stack of the pull transistor in the second group of field effect transistors to a position above the substrate, so as to be connected to the common layer in the first group of field effect transistors.

According to an embodiment of the present disclosure, a source layer contact hole connected to an upper surface of the source layer of the transmission transistor in the first group of field effect transistors extends downwards in the spacing space to a surface of the intermediate dielectric layer, so as to electrically connect the transmission transistor in the first group of field effect transistors to a bit line terminal.

According to an embodiment of the present disclosure, a source layer contact hole connected to a lower surface of the source layer of the pull-up transistor in the second group of field effect transistors passes through the substrate from the upper surface of the substrate and extends downwards to a surface of the intermediate dielectric layer, so as to electrically connect the pull-up transistor in the second group of field effect transistors to a power supply terminal. A source layer contact hole connected to an upper surface of the source layer of the pull-down transistor in the second group of field effect transistors extends downwards in the spacing space to the surface of the intermediate dielectric layer, so as to electrically connect the pull-down transistor in the second group of field effect transistors to a ground terminal.

According to another aspect of the present disclosure, a method of manufacturing a staggered-layer cell is provided, including: forming a first group of field effect transistors and a second group of field effect transistors spaced apart from the first group of field effect transistors on an upper surface of a substrate, where each of the first group of field effect transistors and the second group of field effect transistors is arranged in a first horizontal direction, each of the first group of field effect transistors and the second group of field effect transistors includes a transmission transistor and stacked pull transistors, and the stacked pull transistors include a pull-down transistor and a pull-up transistor that are stacked in a vertical direction; each of the transmission transistor, the pull-down transistor and the pull-up transistor includes: a channel layer, a source/drain layer connected to the channel layer on opposite sides of the channel layer in the first horizontal direction, and a gate stack that extends in a second horizontal direction intersecting the first horizontal direction and surrounds the channel layer; and the pull-down transistor, the pull-up transistor and the transmission transistor in a same group are coupled to one another through a common layer; forming an intermediate dielectric layer surrounding the first group of field effect transistors, the second group of field effect transistors and the substrate; and forming a first staggered-layer contact hole and a second staggered-layer contact hole in the intermediate dielectric layer to obtain the staggered-layer cell, where the second staggered-layer contact hole is connected to both the gate stack of the pull transistor in the second group of field effect transistors and the common layer of the first group of field effect transistors; the first staggered-layer contact hole is connected to the gate stack of the pull transistor in the first group of field effect transistors, extends in the intermediate dielectric layer to a lower surface of the substrate and passes through the substrate to be connected to the common layer of the second group of field effect transistors, so as to form a staggered-layer structure with the second staggered-layer contact hole, so that the first group of field effect transistors and the second group of field effect transistors are cross-coupled with each other.

According to an embodiment of the present disclosure, the intermediate dielectric layer surrounds the first group of field effect transistors and the second group of field effect transistors; and the method further includes: etching the intermediate dielectric layer from top to form a first opening exposing the source layer of the pull-down transistor in the second group of field effect transistors and a second opening exposing the source layer of the transmission transistor in the first group of field effect transistors, where a spacing space between the first group of field effect transistors and the second group of field effect transistors partially overlaps with a projection of the first opening in the vertical direction, and the spacing space partially overlaps with a projection of the second opening in the vertical direction; filling each of the first opening and the second opening with a conductive material, and sealing the first opening and the second opening; etching the intermediate dielectric layer in the spacing space between the first group of field effect transistors and the second group of field effect transistors from bottom, so as to form a third opening exposing the conductive material in the first opening and a fourth opening exposing the conductive material in the second opening; and filling each of the third opening and the fourth opening with a conductive material, so as to form, in the intermediate dielectric layer, a source layer contact hole connected to the source layer of the pull-down transistor in the second group of field effect transistors to electrically connect the pull-down transistor in the second group of field effect transistors to a ground terminal, and form, in the intermediate dielectric layer, a source layer contact hole connected to the source layer of the transmission transistor in the first group of field effect transistors to electrically connect the transmission transistor in the first group of field effect transistors to a bit line terminal.

According to an embodiment of the present disclosure, the pull-up transistor and the transmission transistor in the second group of field effect transistors are electrically connected to each other through a first common layer, and the pull-down transistor and the transmission transistor in the second group of field effect transistors are electrically connected to each other through the first common layer and a second common layer. The forming a first staggered-layer contact hole and a second staggered-layer contact hole in the intermediate dielectric layer to obtain the staggered-layer cell includes: etching the intermediate dielectric layer from top to form a fifth opening exposing each of the first common layer, the second common layer, and the gate stack of the pull transistor in the second group of field effect transistors; and filling the fifth opening with a conductive material that contacts each of the first common layer, the second common layer and the gate stack of the pull transistor in the second group of field effect transistors, and sealing the fifth opening, so as to form the second staggered-layer contact hole.

According to an embodiment of the present disclosure, the pull-up transistor and the transmission transistor in the first group of field effect transistors are electrically connected to each other through a third common layer, and the pull-down transistor and the transmission transistor in the first group of field effect transistors are electrically connected to each other through the third common layer and a fourth common layer. The method further includes: etching the intermediate dielectric layer along a surface of the intermediate dielectric layer from top to form a sixth opening exposing the third common layer and the fourth common layer, where the spacing space between the first group of field effect transistors and the second group of field effect transistors partially overlaps with a projection of the sixth opening in the vertical direction; and filling the sixth opening with a conductive material, and sealing the sixth opening. The forming a first staggered-layer contact hole and a second staggered-layer contact hole in the intermediate dielectric layer to obtain the staggered-layer cell further includes: etching the intermediate dielectric layer along the surface of the intermediate dielectric layer from bottom to form a seventh opening exposing both the gate stack of the pull transistor in the second group of field effect transistors and at least one of the third common layer and the fourth common layer; and filling the seventh opening with a conductive material, and sealing the seventh opening, so as to form the first staggered-layer contact hole.

According to an embodiment of the present disclosure, the method further includes: etching the substrate and the intermediate dielectric layer from bottom according to a position where the source layer of the pull-up transistor in the second group of field effect transistors is located, so as to form a source layer contact hole passing through the substrate and the intermediate dielectric layer to be connected to a lower surface of the source layer of the pull-up transistor in the second group of field effect transistors, so that the pull-up transistor in the second group of field effect transistors is electrically connected to a power supply terminal.

According to an embodiment of the present disclosure, each of the first group of field effect transistors and the second group of field effect transistors further includes a lower fin formed by etching the substrate; and a remaining portion of the substrate after etching is connected between the lower fin of the first group of field effect transistors and the lower fin of the second group of field effect transistors. The forming an intermediate dielectric layer surrounding the first group of field effect transistors, the second group of field effect transistors and the substrate includes: etching the remaining portion of the substrate from bottom until a lower surface of the lower fin of the first group of field effect transistors and a lower surface of the lower fin of the second group of field effect transistors are exposed; and depositing a dielectric material on each of the lower surface of the lower fin of the first group of field effect transistors and the lower surface of the lower fin of the second group of field effect transistors, so as to obtain the intermediate dielectric layer.

### BRIEF DESCRIPTION OF THE DRAWINGS

This application contains at least one drawing executed in color. Copies of this patent application with color drawings will be provided by the Office upon request and payment of the necessary fee.

The above and other objectives, features and advantages of the present disclosure will become clearer through the following description of embodiments of the present disclosure with reference to the accompanying drawings.

FIG. 1 schematically shows a schematic diagram of development of integrated circuits according to an embodiment of the present disclosure.

FIG. 2 schematically shows a schematic diagram of an evolution path of core transistor structures of integrated circuits according to an embodiment of the present disclosure.

FIG. 3 schematically shows a schematic diagram of a sequential integration process according to an embodiment of the present disclosure.

FIG. 4 schematically shows a schematic diagram of a self-aligned monolithic integration process according to an embodiment of the present disclosure.

FIG. 5A schematically shows a schematic structural diagram of a staggered-layer cell according to an embodiment of the present disclosure.

FIG. 5B schematically shows a schematic structural diagram of a field effect transistor in a staggered-layer cell according to an embodiment of the present disclosure.

FIG. 6 schematically shows a schematic diagram of an SRAM integrated circuit according to an embodiment of the present disclosure.

FIG. 7 schematically shows a schematic diagram of a single-layer SRAM structure according to an embodiment of the present disclosure.

FIG. 8A schematically shows a schematic diagram of a layered structure of a three-dimensional stacked SRAM structure according to an embodiment of the present disclosure.

FIG. 8B schematically shows a schematic diagram of a top structure in a three-dimensional stacked SRAM structure according to an embodiment of the present disclosure.

FIG. 8C schematically shows a schematic diagram of a bottom structure in a three-dimensional stacked SRAM structure according to an embodiment of the present disclosure.

FIG. 8D schematically shows a schematic diagram of a backside contact in a three-dimensional stacked SRAM structure according to an embodiment of the present disclosure.

FIG. 9A schematically shows a schematic diagram of a layered structure of a staggered-layer cell according to an embodiment of the present disclosure.

FIG. 9B schematically shows a schematic diagram of a top structure in a staggered-layer cell according to an embodiment of the present disclosure.

FIG. 9C schematically shows a schematic diagram of a bottom structure in a staggered-layer cell according to an embodiment of the present disclosure.

FIG. 9D schematically shows a schematic diagram of a backside contact in a staggered-layer cell according to an embodiment of the present disclosure.

FIG. 10A schematically shows a schematic diagram of an axial direction of a staggered-layer cell extending along a first horizontal direction according to an embodiment of the present disclosure.

FIG. 10B schematically shows a schematic diagram of an axial direction of a staggered-layer cell extending along a second horizontal direction according to an embodiment of the present disclosure.

FIG. 11A to FIG. 11E schematically show various axial directions of the SRAM structure in FIG. 8A.

FIG. 12A to FIG. 12E schematically show various axial directions of the staggered-layer cell structure in FIG. 9A.

FIG. 13 schematically shows a flowchart of a method of manufacturing a staggered-layer cell according to an embodiment of the present disclosure.

FIG. 14A to FIG. 53A, FIG. 14B to FIG. 53B, FIG. 45C, FIG. 45D, FIG. 51C, FIG. 51D, FIG. 53C and FIG. 53D schematically show schematic cross-sectional views of a staggered-layer cell along axial directions according to an embodiment of the present disclosure.

FIG. 54 schematically shows a cross-sectional view of a three-dimensional stacked structure according to an embodiment of the present disclosure.

### DETAILED DESCRIPTION OF EMBODIMENTS

In order to make the objectives, technical solutions and advantages of the present disclosure clearer, the present disclosure is further described in detail below in combination with specific embodiments and with reference to the accompanying drawings.

The terms used herein are for describing the specific embodiments only, and are not intended to limit the present disclosure. The terms “including”, “comprising” and the like used herein indicate the existence of the stated features, steps, operations and/or components, but do not exclude the existence or addition of one or more other features, steps, operations or components.

All the terms, including technical and scientific terms, used herein have the same meaning as commonly understood by those skilled in the art unless otherwise defined. It should be noted that the terms used herein should be interpreted as having a meaning consistent with the context of the present specification and should not be interpreted in an idealized or overly rigid manner.

When using expressions such as “at least one of A, B, C, and the like”, they should generally be interpreted according to the meaning of the expression commonly understood by those skilled in the art. For example, “a system including at least one of A, B, and C” should include but be not limited to a system including A alone, B alone, C alone, A and B, A and C, B and C, and/or A, B and C. When using expressions such as “at least one of A, B, C, or the like”, they should generally be interpreted according to the meaning of the expression commonly understood by those skilled in the art. For example, “a system including at least one of A, B, or C” should include but be not limited to a system including A alone, B alone, C alone, A and B, A and C, B and C, and/or A, B and C.

It should also be noted that the directional terms mentioned in the embodiments, such as “up”, “down”, “front”, “back”, “left”, “right”, etc., are only for reference to the directions of the drawings and are not intended to limit the scope of protection of the present disclosure. Throughout the drawings, the same elements are represented by the same or similar reference numerals. Conventional structures or constructions will be omitted when they may cause confusion in the understanding of the present disclosure.

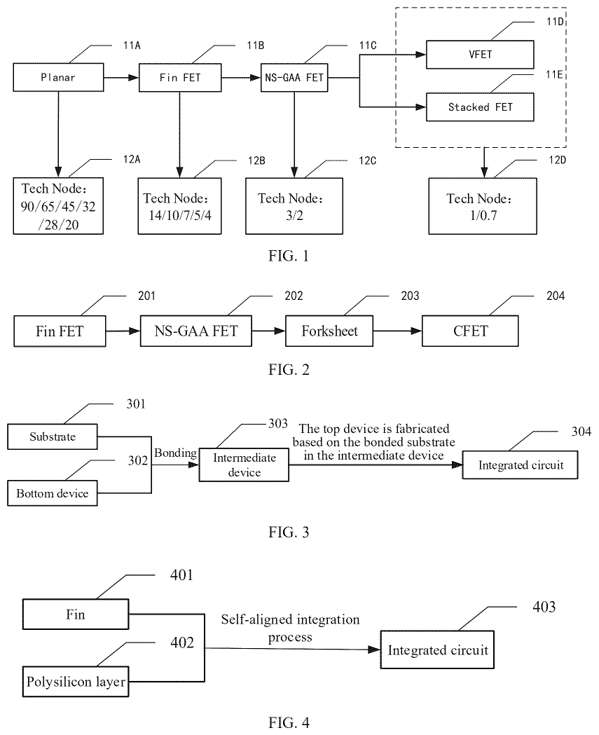

In the embodiments of the present disclosure, the development of integrated circuits is demonstrated by taking the technology development route shown in FIG. 1 as an example. It should be noted that in FIG. 1, “Tech Node” refers to a semiconductor process node, which may be used to represent the critical size that is achievable using the process of integrated circuits. On this basis, referring to the technology development route shown in FIG. 1, it may be seen that the manufacturing processes for integrated circuits are sorted in descending order based on the size represented by the semiconductor process node, which are sequentially Planar 11A (i.e., planar transistor structure), Fin FET 11B, NS-GAA FET 11C, VFET 11D, and Stacked FET 11E. The sizes represented by Tech Node 12A corresponding to Planar 11A are sequentially 90, 65, 45, 32, 28 and 20 in descending order, in nm; the sizes represented by Tech Node 12B corresponding to Fin FET 11B are sequentially 14, 10, 7, 5 and 4 in descending order, in nm; the sizes represented by Tech Node 12C corresponding to NS-GAA FET 11C are sequentially 3 and 2 in descending order, in nm; the sizes represented by Tech Node 12D corresponding to VFET 11D and Stacked FET 11E are sequentially 1 and 0.7 in descending order, in nm.

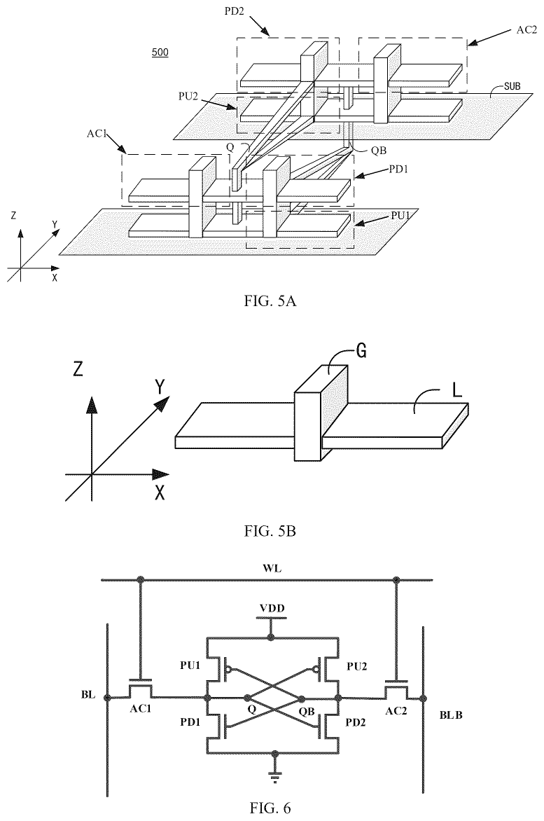

Further, as shown in FIG. 2, in the evolution path of the core transistor structure of integrated circuits, the core transistor structure develops from Fin FET 201 to NS-GAA FET 202, Forksheet 203, and further to the three-dimensional stacked integrated transistor within a single chip, namely 3DS FET or CFET (Complementary Field Effect Transistor) 204, so as to obtain higher integration density and overall performance.

As shown in FIG. 3 and FIG. 4, the main process methods for achieving 3DS FET include two categories: one is the sequential integration process (Sequential 3D), and the other is self-aligned monolithic integration process (Monolithic 3D). Taking two transistors stacked one above the other as an example, when the two transistors are manufactured using the sequential integration process, channel materials of the two transistors may be different from each other; when the two transistors are manufactured using the self-aligned monolithic integration process, the channel materials of the two transistors may be the same. For example, the sequential integration process may include: bonding a substrate 301 to an upper part of a bottom device 302 to obtain an intermediate device 303; and manufacturing a top device based on the bonded substrate in the intermediate device, thereby obtaining an integrated circuit 304. The self-aligned monolithic integration process may include growing a polysilicon layer 402 surrounding multiple channel layers directly on a fin structure 401, and then processing it, so as to obtain an integrated circuit 403.

Therefore, the sequential integration process method is simple, but may be limited by performance and resources; the latter self-aligned monolithic integration process method has high integration and superior performance, but is complex and has various process technology challenges.

Specifically, advantages of the sequential integration process include: a flexible architecture design, an adjustable channel material as desired, a flexible arrangement of connections between transistors, etc. Disadvantages of the sequential integration process are mainly reflected in: high resource consumption, limitations of the manufacturing process, bonding, isolation space between N-P, thermal budget and lithography alignment.

Advantages of the self-aligned monolithic integration process include: low resource consumption, precise process control, such as self-aligned top and bottom devices, narrow isolation space between N-P, etc. Disadvantages of the self-aligned monolithic integration process are mainly reflected in: high process difficulty, such as processes with high aspect ratios, interconnections between devices, etc.

On this basis, the present disclosure provides a staggered-layer cell and a manufacturing method therefor, so as to obtain a CFET device with a staggered-layer structure and a high integration (namely a staggered-layer cell) through a simple process. Specifically, the staggered-layer cell includes: a first group of field effect transistors, a second group of field effect transistors, and an intermediate dielectric layer. The first group of field effect transistors and the second group of field effect transistors are arranged on an upper surface of the substrate, where each of the first group of field effect transistors and the second group of field effect transistors is arranged in a first horizontal direction. The intermediate dielectric layer surrounds the substrate, the first group of field effect transistors and the second group of field effect transistors. Each of the first group of field effect transistors and the second group of field effect transistors includes a transmission transistor and stacked pull transistors, and the stacked pull transistors include a pull-down transistor and a pull-up transistor that are stacked in a vertical direction. Each of the transmission transistor, the pull-down transistor and the pull-up transistor includes: a channel layer; a source/drain layer connected to the channel layer on opposite sides of the channel layer in the first horizontal direction; and a gate stack that extends in a second horizontal direction intersecting with the first direction and surrounds the channel layer. The pull-down transistor, the pull-up transistor and the transmission transistor in a same group are coupled to one another through a common layer. A first staggered-layer contact hole connected to the gate stack of the pull transistor in the first group of field effect transistors, extends in the intermediate dielectric layer to a lower surface of the substrate, and passes through the substrate to be connected to a common layer of the second group of field effect transistors, so that the first staggered-layer contact hole and a second staggered-layer contact hole form a staggered-layer structure, where the second staggered-layer contact hole is used to connect the gate stack of the pull transistor in the second group of field effect transistors to the common layer of the first group of field effect transistors. In this way, the first group of field effect transistors and the second group of field effect transistors are cross-coupled with each other.

FIG. 5A schematically shows a schematic diagram of a staggered-layer cell according to an embodiment of the present disclosure. FIG. 5B schematically shows a schematic diagram of a field effect transistor in a staggered-layer cell according to an embodiment of the present disclosure. It should be noted that in FIG. 5A and FIG. 5B, the extension direction of the X-axis is defined as the first horizontal direction, the extension direction of the Y-axis is defined as the second horizontal direction intersecting the first horizontal direction, and the extension direction of the Z-axis is defined as the vertical direction. In an embodiment of the present disclosure, the first horizontal direction and the second horizontal direction may be perpendicular to each other in a same horizontal plane. The vertical direction may be a direction perpendicular to the horizontal plane.

As shown in FIG. 5A, the staggered-layer cell 500 in this embodiment includes: a first group of field effect transistors and a second group of field effect transistors arranged on the upper surface of the substrate SUB in the first horizontal direction, and an intermediate dielectric layer surrounding the substrate SUB, the first group of field effect transistors and the second group of field effect transistors. The structure of each field effect transistor in the embodiments of the present disclosure is shown in FIG. 5B. The field effect transistor shown in FIG. 5B includes a gate structure G surrounding a channel layer such as a nanosheet or a nanowire (where the channel layer surrounded by the gate structure G is not shown in the perspective view of FIG. 5A), and a source/drain layer L located on opposite sides of the gate structure G and connected to the channel layer.

Each field effect transistor shown in FIG. 5A may be used as a transmission transistor, a pull transistor, or the like according to actual needs. Here, the transmission transistor may be a transistor for transmitting write data from a bit line. The pull transistor may include a pull-up transistor and a pull-down transistor. The pull-up transistor may be a transistor for pulling up a node level. The pull-down transistor may be a transistor for pulling down a node level. In addition, in FIG. 5A, in order to avoid blocking the structure of the staggered-layer cell 500, the intermediate dielectric layer is omitted from FIG. 5A. It should be understood that in the embodiments of the present disclosure, the intermediate dielectric layer may be arranged between structures in the staggered-layer cell 500 as desired, so as to ensure electrical isolation between the field effect transistors in the staggered-layer cell 500.

With continued reference to FIG. 5A, two substrates SUB arranged in a second horizontal direction are shown in FIG. 5A. A plurality of field effect transistors integrated into an integral structure are arranged on each of the two substrates SUB. Based on this, for ease of description, in the present disclosure, the plurality of field effect transistors located on the substrate SUB at the lower left of FIG. 5A are defined as the first group of field effect transistors, which are defined as being located in the front of the space shown in FIG. 5A; and the transistors located on the substrate at the upper right of FIG. 5A are defined as the second group of field effect transistors, which are defined as being located in the rear of the space shown in FIG. 5A. The first group of field effect transistors and the second group of field effect transistors each include stacked field effect transistors. For example, the first group of field effect transistors and the second group of field effect transistors each include a transmission transistor and stacked pull transistors, and the stacked pull transistors include a pull-down transistor and a pull-up transistor that are stacked in the vertical direction. Each of the transmission transistor, the pull-down transistor and the pull-up transistor includes: a channel layer; a source/drain layer connected to the channel layer on opposite sides of the channel layer in the first horizontal direction; and a gate stack which extends in the second horizontal direction intersecting the first horizontal direction and surrounds the channel layer. It should be noted that in the embodiments of the present disclosure, the transmission transistor may be stacked with another transistor, and the actual function of the another transistor may be determined as desired, which will not be described in detail in the present disclosure.

Hereinafter, the field effect transistors shown in FIG. 5A are defined as pull transistors or transmission transistors, so as to facilitate the understanding of the structure of the staggered-layer cell 500 in the embodiments of the present disclosure. It should be understood that the following is only an example, and the function(s) of the field effect transistors in the staggered-layer cell 500 may be set by those skilled in the art as desired.

For example, the transistor located at the upper left in the first group of field effect transistors is defined as a transmission transistor AC1; the transistor located at the upper right in the first group of field effect transistors is defined as a pull-down transistor PD1; and the transistor located at the lower right in the first group of field effect transistors is defined as a pull-up transistor PU1. It may be seen from FIG. 5A that the transmission transistor AC1 and the pull-down transistor PD1 are coupled with each other through a common layer. In addition, in the first group of field effect transistors, the common layer in the upper layer and the common layer in the lower layer are coupled to each other through a connection structure. Based on this, electrical connections between the transmission transistor AC1, the pull-up transistor PU1 and the pull-down transistor PD1 may be achieved. In addition, the common layers for electrical connections between the transmission transistor AC1, the pull-up transistor PU1 and the pull-down transistor PD1 respectively correspond to first source/drain layers of the transmission transistor AC1, the pull-up transistor PU1 and the pull-down transistor PD1. Here, the transmission transistor AC1 may be electrically connected to a bit line terminal through a source layer contact hole connected to a second source/drain layer located on the other side of the gate structure of the transmission transistor AC1, and the transmission transistor AC1 may be electrically connected to a word line terminal through a gate contact hole connected to the gate structure G of the transmission transistor AC1. The pull-up transistor PU1 may be electrically connected to a power supply terminal through a source layer contact hole connected to a second source/drain layer located on the other side of the gate structure of the pull-up transistor PU1, and the pull-down transistor PD1 may be electrically connected to a ground terminal through a source layer contact hole connected to a second source/drain layer located on the other side of the gate structure of the pull-down transistor PD1. Based on this, the stacked pull transistors in the first group of field effect transistors may form an inverter, the pull-up transistor PU1 may achieve a level of the pull-up common layer, and the pull-down transistor PD1 may achieve a level of the pull-down common layer.

Correspondingly, the transistor located at the upper right in the second group of field effect transistors is defined as a transmission transistor AC2; the transistor located at the lower left in the second group of field effect transistors is defined as a pull-down transistor PD2; and the transistor located at the upper left in the second group of field effect transistors is defined as a pull-up transistor PU2. It may be seen from FIG. 5A that the transmission transistor AC2 and the pull-down transistor PU2 are coupled with each other through a common layer. In addition, in the second group of field effect transistors, the common layer in the upper layer and the common layer in the lower layer are coupled to each other through a connection structure. Based on this, electrical connections between the transmission transistor AC2, the pull-up transistor PU2 and the pull-down transistor PD2 may be achieved. In addition, the common layers for the electrical connections between the transmission transistor AC2, the pull-up transistor PU2 and the pull-down transistor PD2 respectively correspond to first source/drain layers of the transmission transistor AC2, the pull-up transistor PU2 and the pull-down transistor PD2. Here, the transmission transistor AC2 may be electrically connected to a bit line terminal through a source layer contact hole connected to a second source/drain layer located on the other side of the gate structure of the transmission transistor AC2, and the transmission transistor AC2 may be electrically connected to a word line terminal through the gate contact hole connected to the gate structure G of the transmission transistor AC2. The pull-up transistor PU2 may be electrically connected to a power supply terminal through a source layer contact hole connected to a second source/drain layer located on the other side of the gate structure of the pull-up transistor PU2, and the pull-down transistor PD2 may be electrically connected to a ground terminal through a source layer contact hole connected to a second source/drain layer located on the other side of the gate structure of the pull-down transistor PD2. Based on this, the stacked pull transistors in the second group of field effect transistors may form an inverter, the pull-up transistor PU2 may achieve a level of the pull-up common layer, and the pull-down transistor PD2 may achieve a level of the pull-down common layer.

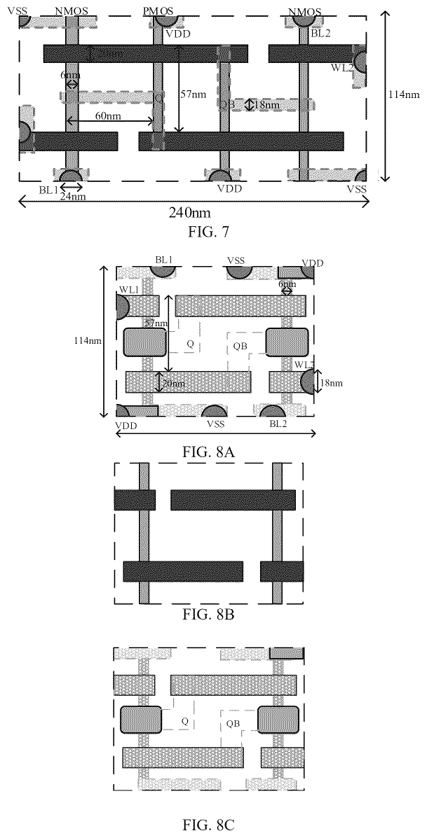

On this basis, by cross-coupling the first group of field effect transistors and the second group of field effect transistors, an SRAM structure (static random-access memory) may be formed. As shown in FIG. 6, SRAM is the core unit circuit of integrated circuits, and continuously reducing the SRAM cell area is the main theme of integrated circuit development. Transistors (3DS-FET or CFET) with three-dimensional stacked structures may be used to greatly reduce the SRAM cell area by more than 30%. Referring to FIG. 7 and FIG. 8A, it may be known from the comparison between the single-layer SRAM structure of FIG. 7 and the double-layer SRAM structure in FIG. 8A that an area of the three-dimensional stacked structure implemented in FIG. 8A is less than an area of the two-dimensional structure in FIG. 7. Further, the three-dimensional stacked structure in FIG. 8A may be divided into a top structure and a bottom structure. The top structure may be implemented based on NMOS, and the bottom structure may be implemented based on PMOS. The top structure and the bottom structure may be connected based on a backside contact (BSCON) and a back gate contact (BGC). On this basis, FIG. 8B and FIG. 8C respectively show the top structure and the bottom structure of the three-dimensional stacked structure in FIG. 8A. FIG. 8D schematically shows the back contact of the three-dimensional stacked structure in FIG. 8A by means of a filling pattern.

According to an implementation of the cross-coupling in an embodiment of the present disclosure, a first staggered-layer contact hole QB connected to the gate stack of the pull transistor in the first group of field effect transistors extends in the intermediate dielectric layer to the lower surface of the substrate SUB and passes through the substrate SUB to be connected to the common layer of the second group of field effect transistors, so that the first staggered-layer contact hole QB and a second staggered-layer contact hole Q form a staggered-layer structure, where the second staggered-layer contact hole Q is used to connect the gate stack of the pull transistor in the second group of field effect transistors to the common layer of the first group of field effect transistors. In this way, the first group of field effect transistors and the second group of field effect transistors are cross-coupled with each other. Here, in the case of implementing SRAM based on the staggered-layer cell in the present disclosure, the first staggered-layer contact hole QB may be electrically connected to a first signal output terminal, and the second staggered-layer contact hole Q may be electrically connected to a second signal output terminal.

Specifically, it may be seen from FIG. 5A that the first group of field effect transistors and the second group of field effect transistors are arranged along the second horizontal direction with a spacing space arranged between the two groups. The first staggered-layer contact hole QB extends from the gate stack of the pull transistor in the first group of field effect transistors to the spacing space so as to the lower surface of the substrate SUB, and passes through the substrate to be connected to the common layer in the second group of field effect transistors. The second staggered-layer contact hole Q extends from the gate stack of the pull transistor in the second group of field effect transistors to the spacing space so as to the above of the substrate to be connected to the common layer in the first group of field effect transistors. The spacing space is filled with a dielectric material used as the intermediate dielectric layer.

In FIG. 5A, for convenience, the electrical connection configurations of the first staggered-layer contact hole QB and the second staggered-layer contact hole Q are schematically shown, however, the physical connection manner thereof is only schematic. Those skilled in the art will know the physical morphologies of the first staggered-layer contact hole QB and the second staggered-layer contact hole Q and their physical connections with other components based on the following description.

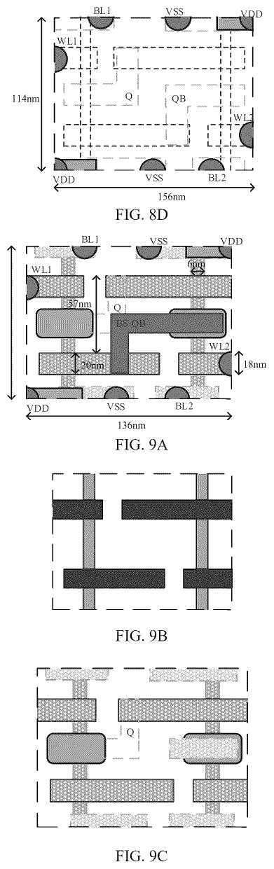

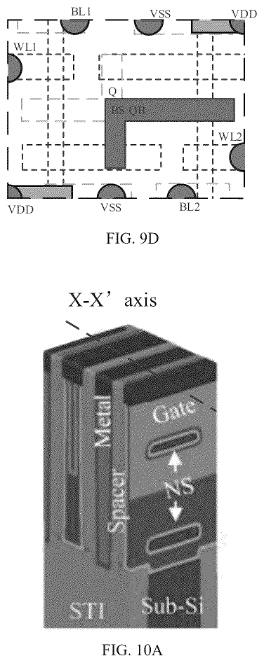

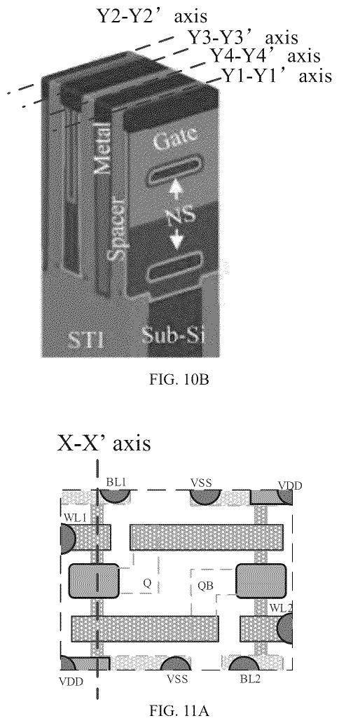

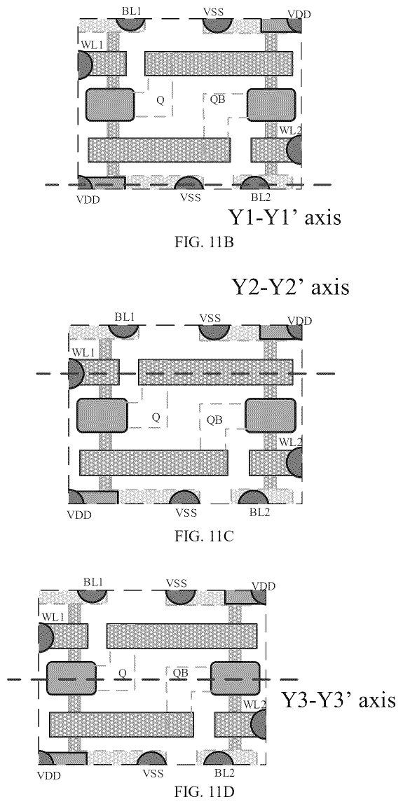

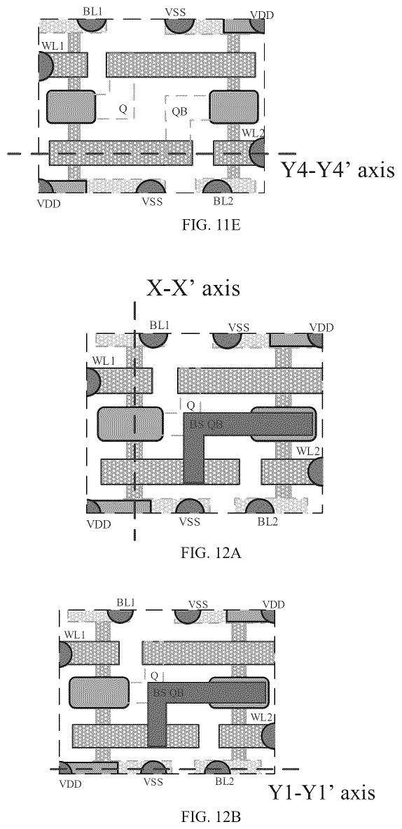

Based on the above implementation of cross-coupling, the area of the SRAM cell may be further reduced on the basis of the three-dimensional stacked structure. FIG. 9A shows a circuit topology diagram of the three-dimensional stacked structure of the above staggered-layer cell. FIG. 9B and FIG. 9C respectively show the top structure and the bottom structure of the three-dimensional stacked structure in FIG. 9A. FIG. 9D schematically shows the backside contact of the three-dimensional stacked structure in FIG. 9A by means of a filling pattern.

Based on this, in the present disclosure, the second staggered-layer contact hole Q is connected to the gate stack of the pull transistor in the second group of field effect transistors and extends in the intermediate dielectric layer to be connected to the common layer of the first group of field effect transistors. In addition, the first staggered-layer contact hole QB is connected to the gate stack of the pull transistor in the first group of field effect transistors, extends in the intermediate dielectric layer to the lower surface of the substrate SUB and passes through the substrate SUB to be connected to the common layer of the second group of field effect transistors. As such, a local interconnection between the common layer of the second group of field effect transistors and the gate stack of the pull transistor in the first group of field effect transistors may be achieved through the back gate contact. Therefore, the first staggered-layer contact hole QB and the second staggered-layer contact hole Q, the storage bits of which are opposite to each other, form a staggered-layer structure with physically symmetrical upper and lower layers, so that it is possible to greatly reduce the in-plane area of an integrated circuit implemented based on the staggered-layer cell while maintaining a simple manufacturing process. For example, it may be seen from the comparison between FIG. 8A and FIG. 9A that since the first staggered-layer contact hole QB and the second staggered-layer contact hole Q form a staggered-layer structure, the first staggered-layer contact hole QB and the second staggered-layer contact hole Q partially overlap with each other in the Z-axis direction. As such, the size in the horizontal direction is reduced, that is, the 156 nm in FIG. 8A is reduced to 136 nm in FIG. 9A. The storage bits of such structure are manufactured in a layered manner, so that it is possible to significantly reduce the CFET-based SRAM cell area. It should be noted that the dimensions marked in the drawings of the present disclosure are exemplary and are not intended to limit the actual dimensions of the staggered-layer cell in the present disclosure.

In the embodiments of the present disclosure, the various source layer contact holes may extend in the intermediate dielectric layer and be exposed to a same surface of the intermediate dielectric layer. For example, the source layer contact hole connected to the upper surface of the source layer of the transmission transistor AC1 in the first group of field effect transistors extends downwards in the spacing space to a surface of the intermediate dielectric layer, so as to electrically connect the transmission transistor AC1 in the first group of field effect transistors to the bit line terminal. The source layer contact hole connected to the lower surface of the source layer of the transmission transistor AC2 in the second group of field effect transistors passes through the substrate SUB and extends in the spacing region to the surface of the intermediate dielectric layer, so as to electrically connect the transmission transistor AC2 in the second group of field effect transistors to the bit line terminal.

For another example, the source layer contact hole connected to the lower surface of the source layer of the pull-down transistor PD1 in the first group of field effect transistors passes through the substrate SUB from the upper surface of the substrate SUB and extends downwards to the surface of the intermediate dielectric layer, so as to electrically connect the pull-down transistor PD1 in the first group of field effect transistors to the ground terminal. The source layer contact hole connected to the upper surface of the source layer of the pull-up transistor PU1 in the first group of field effect transistors extends downwards in the spacing space to the surface of the intermediate dielectric layer, so as to electrically connect the pull-up transistor PU1 in the first group of field effect transistors to the power supply terminal.

For another example, the source layer contact hole connected to the lower surface of the source layer of the pull-up transistor PU2 in the second group of field effect transistors passes through the substrate SUB from the upper surface of the substrate SUB and extends downwards to the surface of the intermediate dielectric layer, so as to electrically connect the pull-up transistor PU2 in the second group of field effect transistors to the power supply terminal. The source layer contact hole connected to the upper surface of the source layer of the pull-down transistor PD2 in the second group of field effect transistors extends downwards in the spacing space to the surface of the intermediate dielectric layer, so as to electrically connect the pull-down transistor PD2 in the second group of field effect transistors to the ground terminal.

In order to provide a better understanding of the structure of the staggered-layer cell in the present disclosure, the present disclosure will be explained below in combination with the method of manufacturing the staggered-layer cell. Here, taking SRAM as an example, the various axial directions of the staggered-layer cell defined in the embodiments of the present disclosure are shown in FIG. 10A and FIG. 10B.

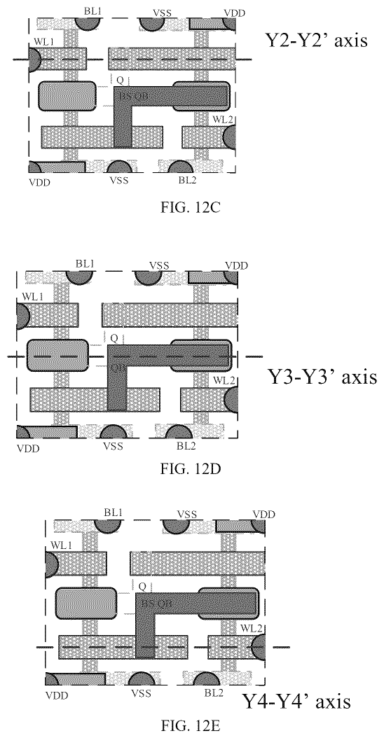

FIG. 11A to FIG. 11E schematically show the various axial directions of the three-dimensional stacked structure in FIG. 8A. FIG. 12A to FIG. 12E schematically show the various axial directions of the three-dimensional structure of the staggered-layer cell of the present disclosure in FIG. 9A. Here, the X-X′ axial direction is consistent with the extension direction of the X axis in FIG. 10. The Y1-Y1′ axial direction, the Y2-Y2′ axial direction, the Y3-Y3′ axial direction and the Y4-Y4′ axial direction are all consistent with the extension direction of the Y axis in FIG. 10.

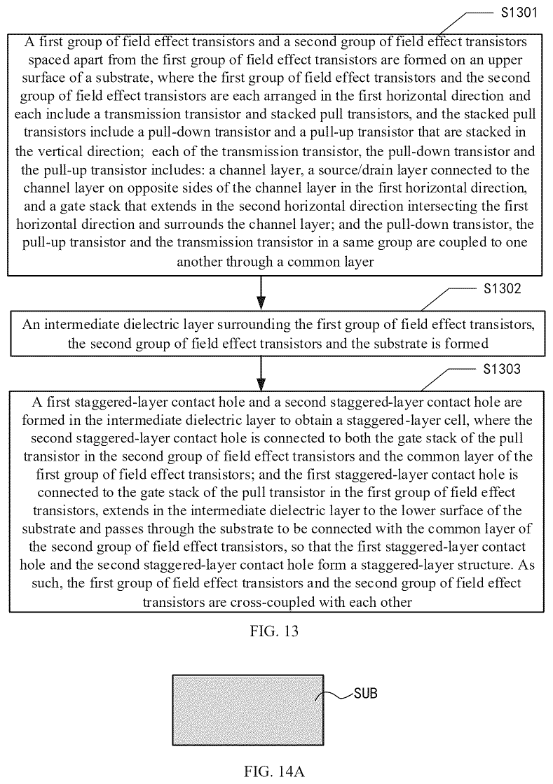

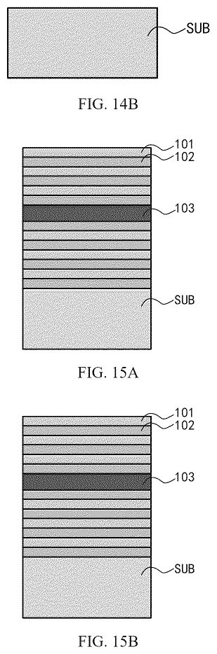

FIG. 13 schematically shows a flowchart of a method of manufacturing a staggered-layer cell according to an embodiment of the present disclosure.

As shown in FIG. 13, the method of manufacturing the staggered-layer cell in this embodiment includes operations S1301 to S1303.

In operation S1301, a first group of field effect transistors and a second group of field effect transistors spaced apart from the first group of field effect transistors are formed on the upper surface of the substrate, where each of the first group of field effect transistors and the second group of field effect transistors is arranged in the first horizontal direction; each of the first group of field effect transistors and the second group of field effect transistors includes a transmission transistor and stacked pull transistors, and the stacked pull transistors include a pull-down transistor and a pull-up transistor that are stacked in the vertical direction; each of the transmission transistor, the pull-down transistor and the pull-up transistor includes: a channel layer, a source/drain layer connected to the channel layer on opposite sides of the channel layer in the first horizontal direction, and a gate stack that extends in the second horizontal direction intersecting the first horizontal direction and surrounds the channel layer; and the pull-down transistor, the pull-up transistor and the transmission transistor in a same group are coupled to one another through a common layer.

In operation S1302, an intermediate dielectric layer surrounding the first group of field effect transistors, the second group of field effect transistors and the substrate is formed.

In operation S1303, a first staggered-layer contact hole and a second staggered-layer contact hole are formed in the intermediate dielectric layer to obtain a staggered-layer cell, where the second staggered-layer contact hole is connected to both the gate stack of the pull transistor in the second group of field effect transistors and the common layer of the first group of field effect transistors; and the first staggered-layer contact hole is connected to the gate stack of the pull transistor in the first group of field effect transistors, extends in the intermediate dielectric layer to the lower surface of the substrate and passes through the substrate to be connected to the common layer of the second group of field effect transistors, so that the first staggered-layer contact hole and the second staggered-layer contact hole form a staggered-layer structure. As such, the first group of field effect transistors and the second group of field effect transistors are cross-coupled with each other.

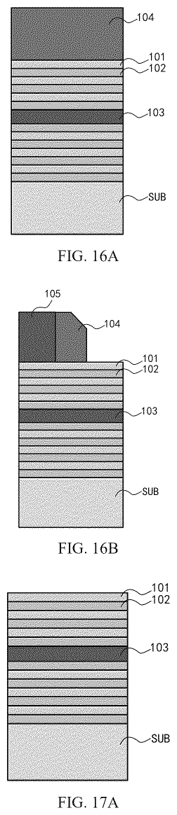

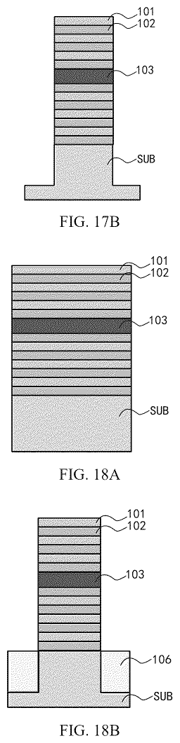

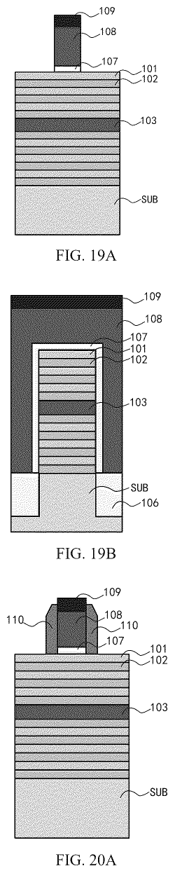

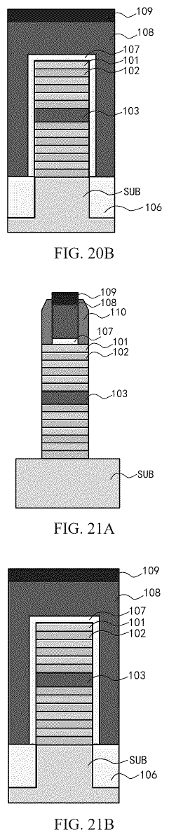

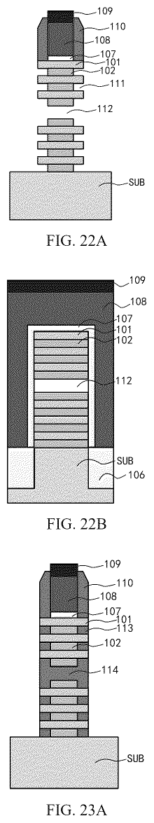

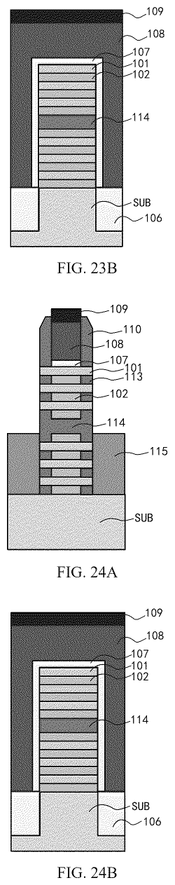

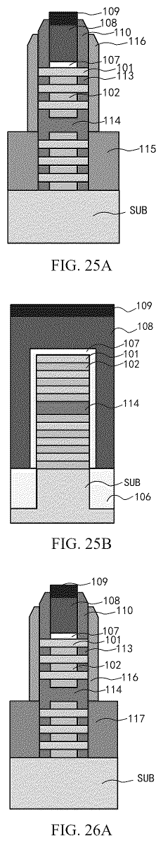

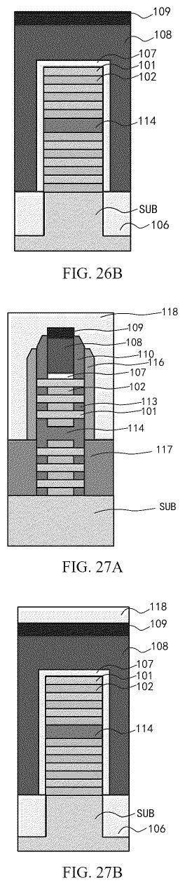

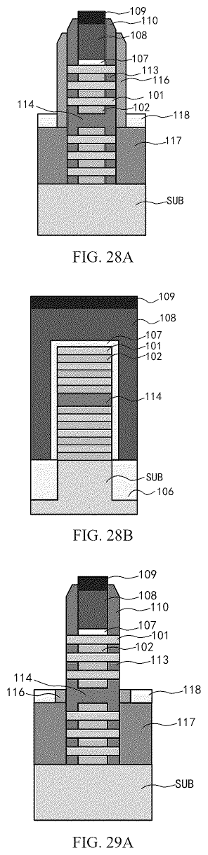

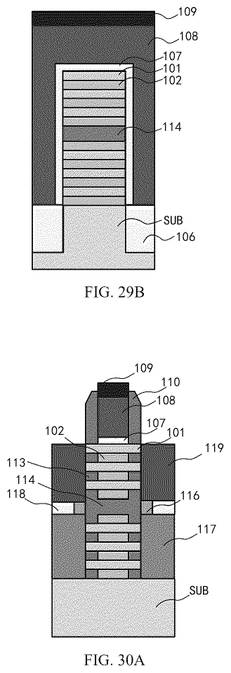

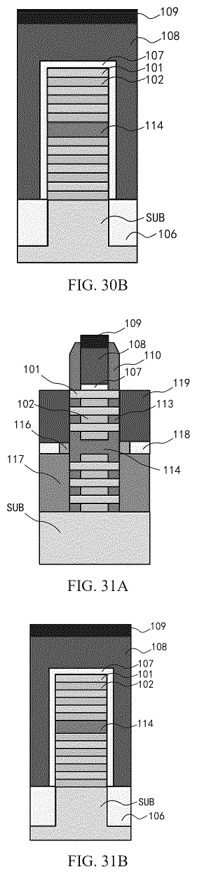

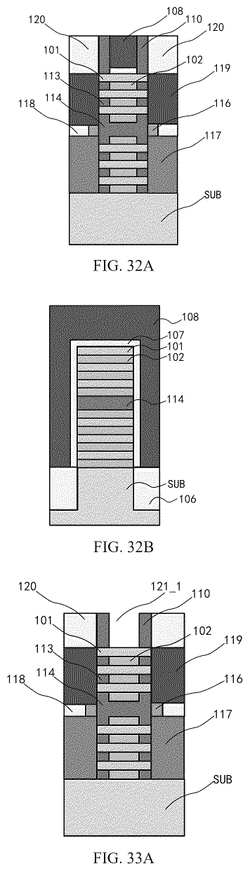

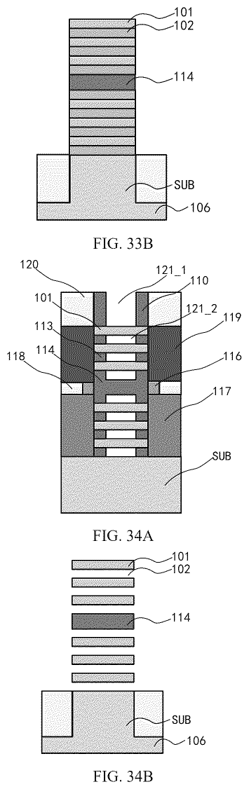

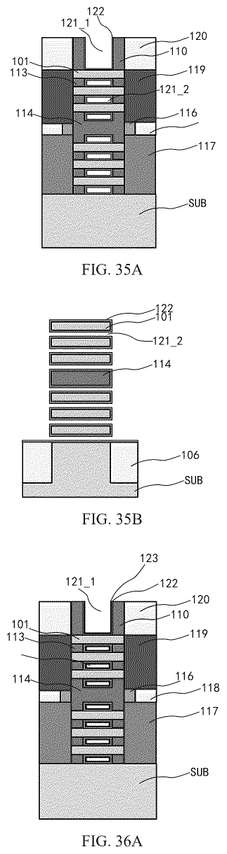

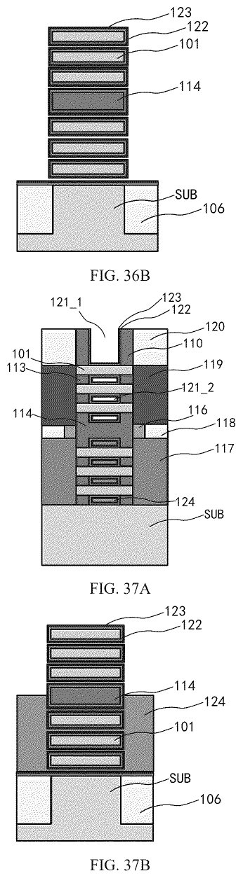

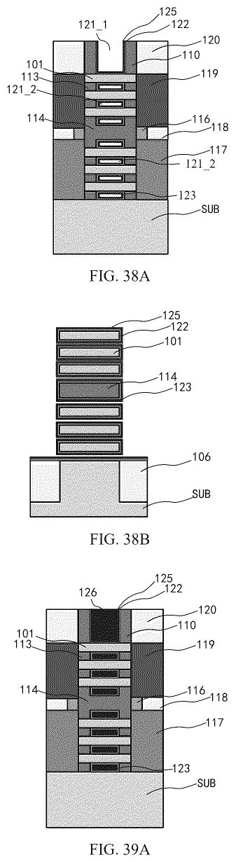

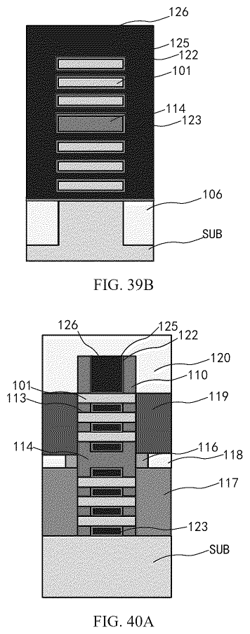

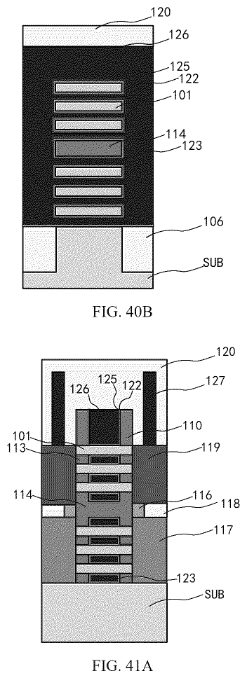

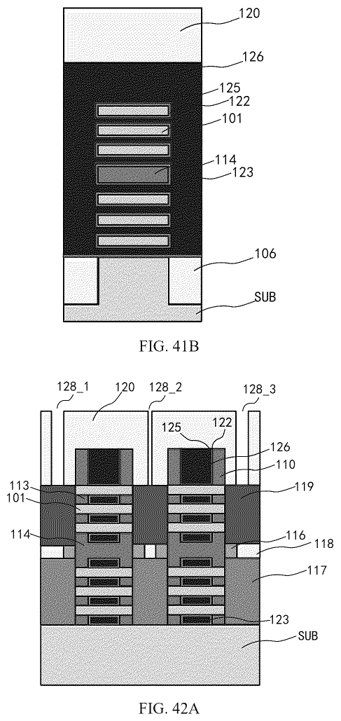

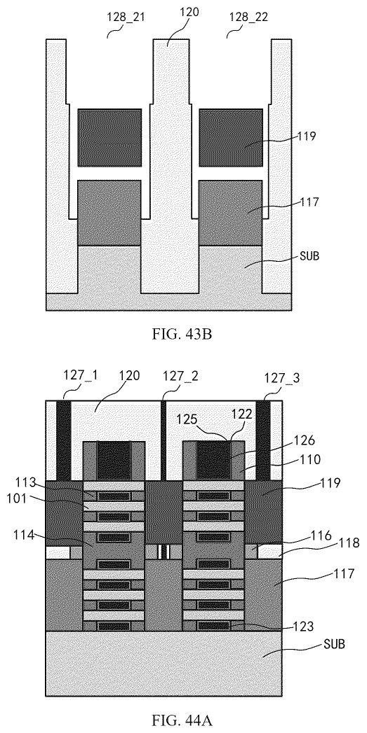

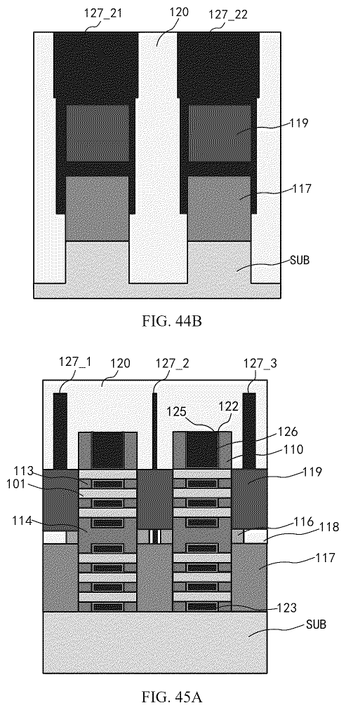

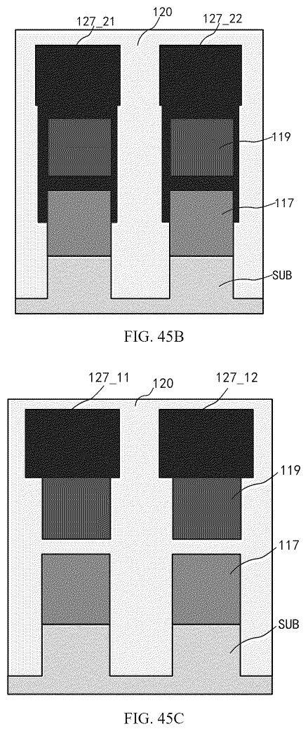

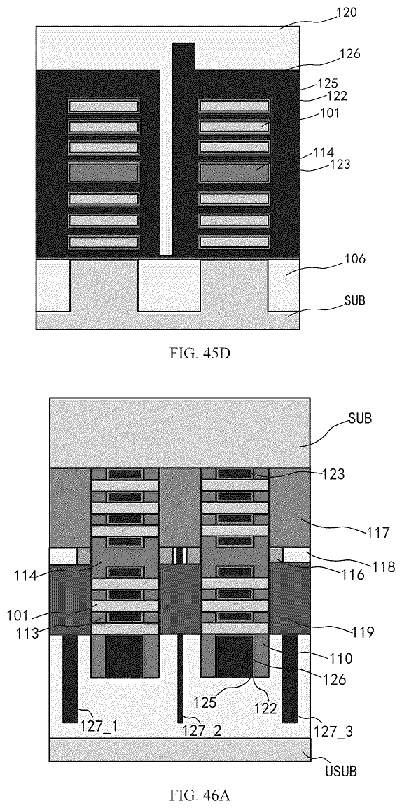

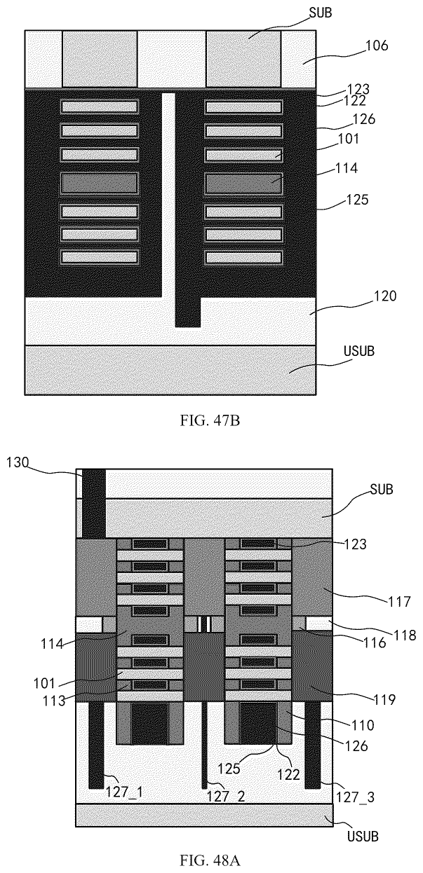

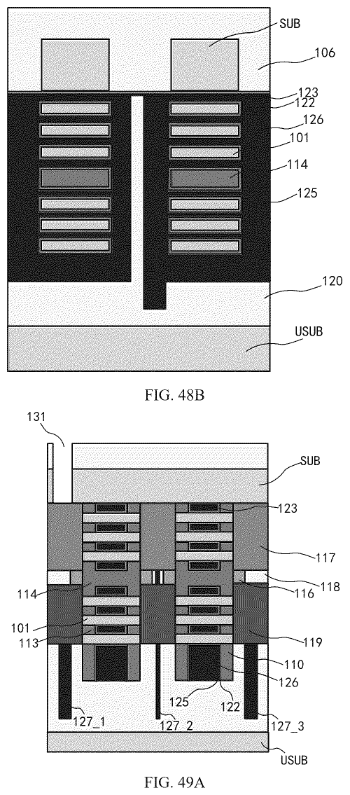

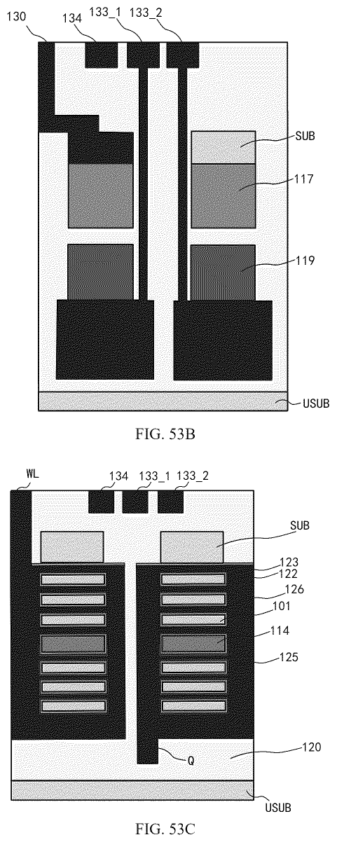

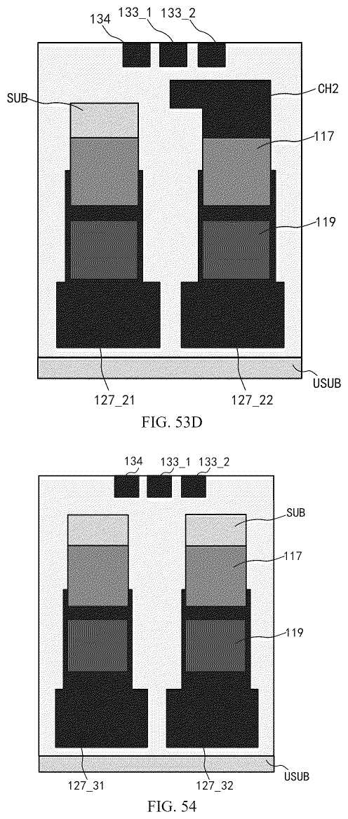

In order to provide a better understanding of the method of manufacturing the staggered-layer cell, the following explains the embodiments of the present disclosure based on the cross-sectional views along the various axial directions, namely FIG. 14A to FIG. 53A, FIG. 14B to FIG. 53B, FIG. 45C, FIG. 45D, FIG. 51C, FIG. 51D, FIG. 53C and FIG. 53D, during the manufacturing process of the staggered-layer cell. It should be noted that in FIGS. 14A to 53A, 14B to 53B, 45C, 45D, 51C, 51D, 53C and 53D shown in the present disclosure, when the numbers in the figure numbers of multiple drawings are the same, the manufacturing processes corresponding to the multiple drawings are the same. When there are multiple drawings having the same figure number but different letters, the multiple drawings correspond to the same manufacturing process but different axial directions. For example, FIG. 14A and FIG. 14B are respectively cross-sectional views along two axial directions in the same manufacturing process.

Taking a group of stacked field effect transistors as an example, FIG. 14A to FIG. 15A are cross-sectional views along the X-X′ axis in the process of manufacturing the staggered-layer cell. FIG. 14B to FIG. 15B are cross-sectional views along the Y4-Y4′ axis in the process of manufacturing the staggered-layer cell. Referring to FIG. 14A to FIG. 15A, and FIG. 14B to FIG. 15B, a material of the substrate SUB may include silicon, etc. Pretreatment operations such as well lithography, ion implantation, annealing and cleaning may be performed on the substrate SUB in sequence. After that, the lower stack, the intermediate layer 103 and the upper stack are sequentially arranged on the pretreated substrate SUB using an epitaxial growth process. Each of the lower stack and the upper stack includes channel layers 101 and sacrificial layers 102 that are alternatively arranged. Here, materials of the sacrificial layer 102 and the intermediate layer 103 may be the same, such as SiGe, Si, or the like. A material of the channel layer 101 may be doped silicon, etc. A channel layer 101 located above the intermediate layer 103 and a channel layer 101 located below the intermediate layer 103 may have the same doping element or different doping elements.

In a first embodiment of the present disclosure, the material of the channel layer 101 located above the intermediate layer 103 may be p-type doped silicon, and the material of the channel layer 101 located below the intermediate layer 103 may be n-type doped silicon. In a second embodiment of the present disclosure, the material of the channel layer 101 located above the intermediate layer 103 may be n-type doped silicon, and the material of the channel layer 101 located below the intermediate layer 103 may be p-type doped silicon. In a third embodiment of the present disclosure, the material of the channel layer 101 located above the intermediate layer 103 and the material of the channel layer 101 located below the intermediate layer 103 may be both n-type doped silicon, or both p-type doped silicon.

FIG. 16A to FIG. 18A are cross-sectional views along the X-X′ axis in the process of manufacturing the staggered-layer cell. FIG. 16B to FIG. 18B are cross-sectional views along the Y4-Y4′ axis in the process of manufacturing the staggered-layer cell. Referring to FIG. 16A to FIG. 18A, and FIG. 16B to FIG. 18B, a spacer 104 may be formed by a spacer image transfer (SIT) process. A material of the spacer 104 may be silicon nitride, etc. In the embodiments of the present disclosure, a mandrel 105 may be formed on the upper stack, and the mandrel 105 may be patterned using a photolithography process to obtain a linear pattern extending in the X direction. Here, a material of the mandrel 105 may be polycrystalline silicon, amorphous silicon, or the like. The spacer 104 is formed in the above region, and the patterned mandrel 105 is removed after the spacer 104 is formed, so that only the spacer 104 is left on the stack, thereby completing the manufacturing of the spacer 104. On this basis, the upper stack, the intermediate layer 103, the lower stack and the substrate SUB may be etched using an anisotropic etching process based on the pattern of the spacer 104, so as to form a fin on the substrate SUB and a substrate etching region distributed on opposite sides of the fin in the first horizontal direction. In the substrate etching region, a dielectric material 106 is deposited, and the dielectric material 106 is etched to a level either below or flush with an upper surface of a lower fin formed by the substrate using an etch-back process, so that the dielectric material 106 serves as a shallow trench isolation member. The dielectric material in the embodiments of the present disclosure may include silicon dioxide, silicon nitride, or the like.

FIG. 19A to FIG. 23A are cross-sectional views along the X-X′ axis in the process of manufacturing the staggered-layer cell. FIG. 19B to FIG. 23B are cross-sectional views along the Y4-Y4′ axis in the process of manufacturing the staggered-layer cell. Referring to FIG. 19A to FIG. 23A, and FIG. 19B to FIG. 23B, a sacrificial gate spanning over the fin may be formed on the dielectric material 106 using processes such as thermal oxidation, chemical vapor deposition or sputtering. The sacrificial gate includes a gate oxide layer 107, a silicon layer 108 and a mask layer 109 in sequence from bottom to top, where a material of the gate oxide layer 107 may be SiO₂, etc. A material of the silicon layer 108 is amorphous silicon or polycrystalline silicon. A material of the hard mask layer 109 may be oxide, carbide, organic matter, or the like. On this basis, a spacer 110 may be formed on a sidewall of the sacrificial gate using a spacer formation process. A material of the spacer 110 may be SiCNO, etc. The upper stack, the intermediate layer and the lower stack may be etched based on the pattern of the sacrificial gate and the pattern of the spacer 110, thereby exposing the sidewall of the upper stack, the sidewall of the intermediate layer and the sidewall of the lower stack. The intermediate layer 103 and the sacrificial layer 102 may be set to have different etching selectivities, so that the intermediate layer 103 may be etched at a faster rate than the sacrificial layer 102. After the intermediate layer 103 is etched, an opening 112 is formed. An end of the sacrificial layer 102 in the first horizontal direction is recessed relative to the channel layer 101 to form an opening 111. Based on this, a space released within the fin due to the selective etching of the sacrificial layer 102 and the intermediate layer 103 is filled with a dielectric material. A portion of the dielectric material filled at the end of the sacrificial layer 102 serves as an inner spacer 113, and a portion of the dielectric material filled between the lower stack and the upper stack serves as an inter-device isolation layer 114. In this way, the inner spacer 113 and the inter-device isolation layer 114 are synchronously manufactured, so that it is possible to reduce the steps of the manufacturing process and avoid an adverse outcome of misalignment of side edges of the upper and lower field effect transistor in the stacked field effect transistors in the vertical direction due to separately manufacturing the inner spacer 113 and the inter-device isolation layer 114.

FIG. 24A to FIG. 31A are cross-sectional views along the X-X′ axis in the process of manufacturing the staggered-layer cell. FIG. 24B to FIG. 31B are cross-sectional views along the Y4-Y4′ axis in the process of manufacturing the staggered-layer cell. Referring to FIG. 24A to FIG. 31A and FIG. 24B to FIG. 31B, a lower source/drain position defining layer 115 in contact with a channel layer 101 is formed on opposite sides of the channel layer 101 below the inter-device isolation layer 114, and a spacer 116 is formed on the lower source/drain position defining layer 115 using a spacer forming process. Here, a material of the lower source/drain position defining layer 115 may include but is not limited to a-C (amorphous carbon). The formation method of the lower source/drain position defining layer 115 includes but is not limited to spin coating. For example, after depositing a-C, the deposited a-C may be planarized, and the a-C may be etched back to a level not higher than a middle position of the inter-device isolation layer 114. A material of the spacer 116 includes but is not limited to SiNₓ and the like. Here, the spacer 116 is used to protect the channel layer 101 located above the inter-device isolation layer, so as to prevent source/drain from growing at opposite ends of the channel layer 101 of the upper device during the growth process of the source/drain of the lower device. In the case of different types of the upper and lower devices, source/drain materials of the upper and lower devices may be different from each other.

After forming the spacer 116, the lower source/drain position defining layer 115 is removed to expose a sidewall of the channel layer 101 below the inter-device isolation layer 114. On the exposed sidewall of the channel layer 101, a source/drain material is epitaxially grown and in-situ doped, so as to form a source/drain layer 117 connected to the lower stack. Here, the source/drain material may be SiGe or Si. A dielectric material 118 may be deposited on the source/drain layer 117, and the dielectric material 118 may be etched to a level not higher than the inter-device isolation layer 114, so as to electrically isolate the source/drain layer of the upper device from the source/drain layer of the lower device. The spacer 116 may be selectively etched to expose a sidewall of the channel layer 101 above the device isolation layer 114. On the exposed sidewall of the channel layer 101, a source/drain material is epitaxially grown and in-situ doped, so as to form a source/drain layer 119 connected to the upper stack. On this basis, the source/drain layer 117 and the source/drain layer 119 are activated to form the activated source/drain layer 117 and the activated source/drain layer 119.

FIG. 32A to FIG. 41A are cross-sectional views along the X-X′ axis in the process of manufacturing the staggered-layer cell. FIG. 32B to FIG. 41B are cross-sectional views along the Y4-Y4′ axis in the process of manufacturing the staggered-layer cell. Referring to FIG. 32A to FIG. 41A and FIG. 32B to FIG. 41B, a dielectric material 120 is formed on the substrate SUB, and the dielectric material 120 is planarized. The planarization may remove the mask layer 109 in the sacrificial gate and expose the silicon layer 108. After that, the silicon layer 108 and the sacrificial layer 102 are etched using an etch-back process, therefore, on the inner side of the spacer 110 and the inner spacer 113, a cavity 121_1 exposed due to the etching is formed at the original position of the silicon layer 108, and a cavity 121_2 exposed due to the etching is formed at the original position of the sacrificial layer 102.

Gate stacks surrounding the channel layers 101 are sequentially formed on an inner sidewall of the cavity 121_1 and an inner sidewall of the cavity 121_2. The gate stack includes a gate dielectric layer 122 and a P-type work function layer 123. A material of the gate dielectric layer 122 may be a high-k dielectric material, where K represents a dielectric constant. The high-k dielectric material includes one of or a combination of HfO₂, HfSiOₓ, HfON, HfSiON, HfAlOₓ, HfLaOₓ, Al₂O₃, ZrO₂, ZrSiOₓ, Ta₂O₅ or La₂O₃. A material of the P-type work function layer 123 may be titanium nitride, etc. A protective layer 124 is formed on the substrate SUB, and the protective layer 124 is etched until a top surface thereof is located between the top surface and the bottom surface of the inter-device isolation layer 114 to cover the cavity for the lower device, so that the protective layer 124 protects the P-type work function layer 123 located in the cavity below the inter-device isolation layer 114 and exposes the P-type work function layer 123 located in the cavity above the inter-device isolation layer 114.

The P-type work function layer 123 above the inter-device isolation layer 114 is etched by using a selective etching process, and the gate dielectric layer 122 above the inter-device isolation layer 114 is retained. Then, an N-type work function layer 125 surrounding the gate dielectric layer 122 above the inter-device isolation layer 114 is formed. Thus, different gate stacks surrounding channel layers 101 are formed above and below the inter-device isolation layer 114, respectively. Thus, the channel layer 101, the gate stack and the source/drain layer 119 that are located above the inter-device isolation layer form an N-type field effect transistor, and the channel layer 101, the gate stack and the source/drain layer 117 that are located below the inter-device isolation layer form a P-type field effect transistor, thereby obtaining stacked field effect transistors.

It should be understood that the above is only an embodiment of the present disclosure. In the manufacturing process of other embodiments of the present disclosure, an N-type field effect transistor or a P-type field effect transistor may be formed as desired by changing a doping type of a source/drain layer and forming a corresponding type of work function layer. For example, the upper N-type field effect transistor may be formed as a P-type field effect transistor, and/or the lower P-type field effect transistor may be formed as an N-type field effect transistor.

After manufacturing the above-mentioned N-type field effect transistor and P-type field effect transistor, the protective layer 124 is removed to release a cavity below the inter-device isolation layer 114. After that, a conductive material is deposited in all the cavities 121_1 and all the cavities 121_2 to form a conductive layer 126, thereby completing the manufacturing of a gate structure. The conductive material in the embodiments of the present disclosure may include tungsten, etc. After the conductive layer 126 is formed, the conductive layer 126 may be planarized, and a dielectric material may be deposited on the planarized conductive layer 126. On this basis, a contact hole 127 connected to the source/drain layer 119 may be formed in the dielectric material 120.

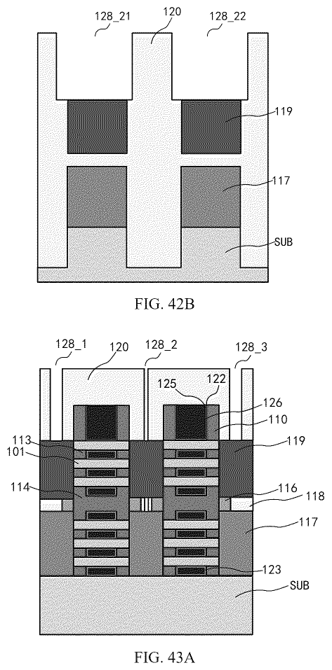

Specifically, taking the four field effect transistors in the first group of field effect transistors and the four field effect transistors in the second group of field effect transistors as an example, FIG. 42A to FIG. 45A are cross-sectional views along the X-X′ axis in the process of manufacturing the staggered-layer cell. FIG. 42B to FIG. 45B are cross-sectional views along the Y3-Y3′ axis in the process of manufacturing the staggered-layer cell. FIG. 45C is a cross-sectional view along the Y1-Y1′ axis in the process of manufacturing the staggered-layer cell. FIG. 45D is a cross-sectional view along the Y2-Y2′ axis in the process of manufacturing the staggered-layer cell.

On this basis, FIGS. 42A to 45A, FIGS. 42B to 45B, FIG. 45C and FIG. 45D show cross-sectional schematic diagrams of a structure in which the above-mentioned eight field effect transistors are integrated. On an upper surface of the dielectric material 120, the dielectric material 120 is etched until the source/drain layer 119 is exposed, so as to form an opening 128_1, an opening 128_2, and an opening 128_3 that are located in the dielectric material 120. Here, the opening 128_2 includes an opening 128_21 corresponding to the first group of field effect transistors and an opening 128_22 corresponding to the second group of field effect transistors. On this basis, the opening 128_2 is further etched based on a position of the source/drain layer 117 which serves as a common layer, so that the opening 128_2 exposes both the source/drain layer 119 and the source/drain layer 117. The openings 128_1, 128_2 and 128_3 are filled with a conductive material, thereby forming contact holes 127_1, 127_2 and 127_3 respectively. Here, the contact hole 127_2 includes a contact hole 127_21 formed by filling the opening 128_21 and a contact hole 127_22 formed by filling the opening 128_22. A dielectric material is deposited on the contact hole 127_1, the contact hole 127_2 and the contact hole 127_3. It should be noted there is a structure above a right conductive layer 126 in FIG. 45D, which protrudes from an upper surface of the conductive layer 126. This structure is used as a connection line extending in a direction (corresponding to the first horizontal direction) perpendicular to the paper surface. In addition, a left conductive layer 126 in FIG. 45D extends to the left side so as to facilitate leading out a pad for connecting a word line terminal from the backside.

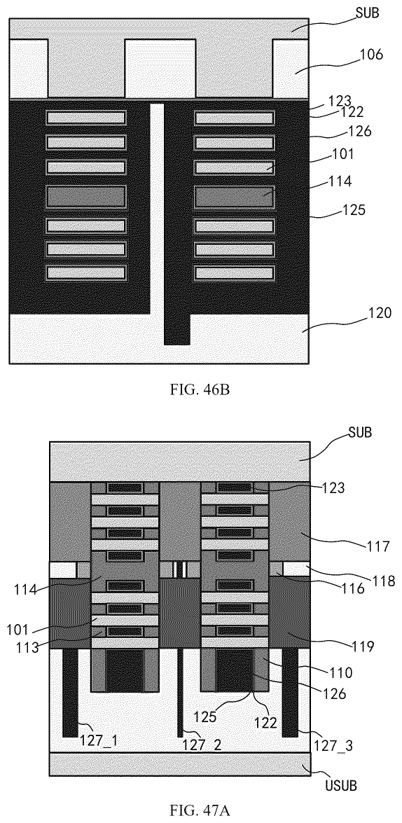

FIG. 46A to FIG. 48A are cross-sectional views along the X-X′ axis in the process of manufacturing the staggered-layer cell. FIG. 46B to FIG. 48B are cross-sectional views along the Y4-Y4′ axis in the process of manufacturing the staggered-layer cell. Refer to FIG. 46A to FIG. 48A, and FIG. 46B to FIG. 48B. It should be noted that in FIG. 46A to FIG. 48A, and FIG. 46B to FIG. 48B, the stacked field effect transistors are inverted for ease of description, and the same applies to the following other figures. It should be noted that hereinafter, the terms “above” and “below” are described based on the staggered-layer cell that is not inverted. After the stacked field effect transistors are inverted, another substrate USUB may be bonded above the stacked field effect transistors, and a material of the substrate USUB is the same as that of the above-mentioned substrate SUB. In the embodiments of the present disclosure, the first group of field effect transistors and the second group of field effect transistors each include a lower fin formed by etching the substrate SUB. The remaining portion of the substrate after etching is connected between the lower fin of the first group of field effect transistors and the lower fin of the second group of field effect transistors. An intermediate dielectric layer surrounding the first group of field effect transistors, the second group of field effect transistors and the substrate is formed, which includes: etching part of the substrate from the bottom until a lower surface of the lower fin of the first group of field effect transistors and a lower surface of the lower fin of the second group of field effect transistors are exposed. A dielectric material is deposited on each of the lower surface of the lower fin of the first group of field effect transistors and the lower surface of the lower fin of the second group of field effect transistors, so as to obtain the intermediate dielectric layer. Thus, the lower fin of the first group of field effect transistors and the lower fin of the second group of field effect transistors may be electrically isolated from each other.

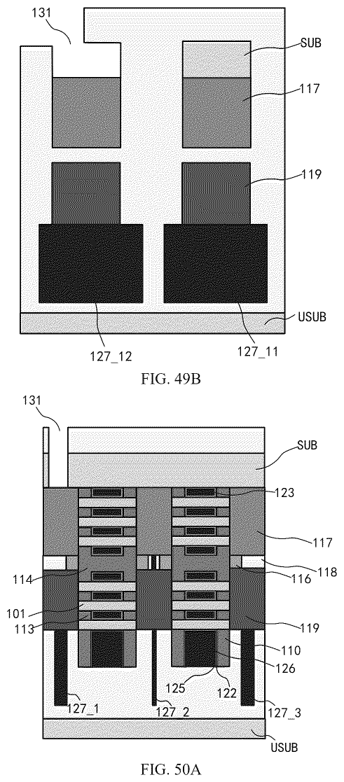

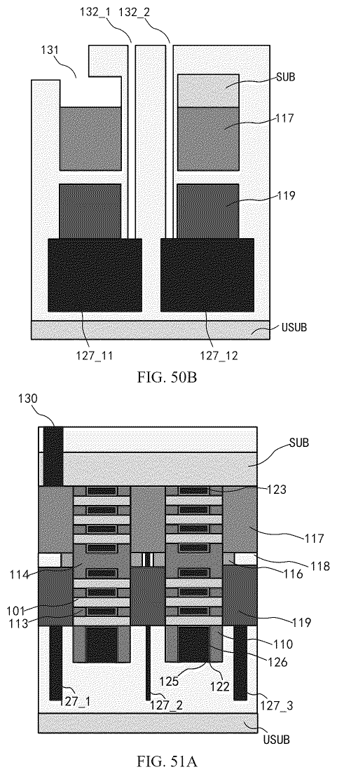

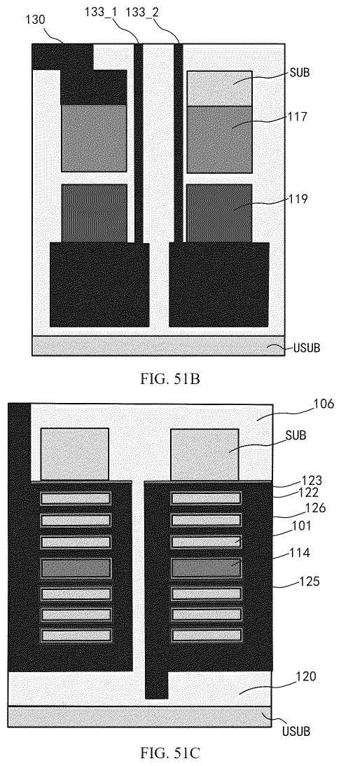

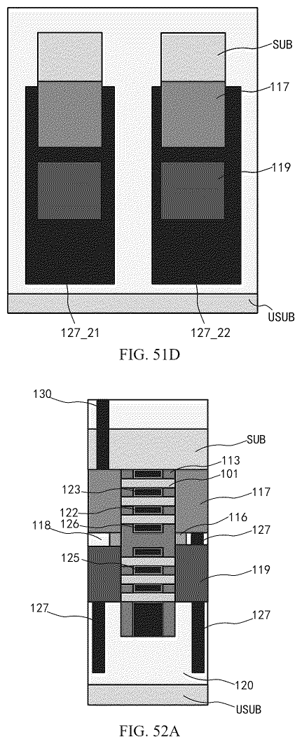

Continuing with the example of the four field effect transistors in the first group of field effect transistors and the four field effect transistors in the second group of field effect transistors, FIG. 49A to FIG. 51A are cross-sectional views along the X-X′ axis in the process of manufacturing the staggered-layer cell. FIG. 49B to FIG. 51B are cross-sectional views along the Y1-Y1′ axis in the process of manufacturing the staggered-layer cell. FIG. 51C is a cross-sectional view along the Y2-Y2′ axis in the process of manufacturing the staggered-layer cell. FIG. 51D is a cross-sectional view along the Y3-Y3′ axis in the process of manufacturing the staggered-layer cell.

Referring to FIG. 49A to FIG. 51A, FIG. 49B to FIG. 51B, FIG. 51C and FIG. 51D, a dielectric material is deposited on a lower side of the substrate SUB, and a lithography process is performed on the dielectric material and the substrate SUB, so as to form an opening 131 exposing the lower source layer, as well as openings 132_1 and 132_2 which expose the conductive material in contact with the upper source layer. A conductive material is deposited into the above-mentioned openings 131, 132_1 and 132_2, so as to form a contact hole in the back of the device through the opening 131 that exposes the lower source layer, and to form an interlayer contact through hole in the back of the device through the openings 132_1 and 132_2 that expose the conductive material in contact with the upper source layer. Here, the conductive material filled in the opening 131 may be used as a back contact hole (BSCON) electrically connected to the power terminal. The conductive materials filled in the openings 132_1 and 132_2 may be used as back interlayer contact through holes (BSVPR) electrically connected to the ground terminal and the bit line terminal respectively.

After depositing the conductive material, the conductive material exposed outside the dielectric material is planarized. According to an embodiment of the present disclosure, the above-mentioned manufacturing method further includes: etching the substrate SUB and the intermediate dielectric layer from the bottom according to a position where the source layer of the pull-up transistor in the second group of field effect transistors is located, so as to form a source layer contact hole that passes through the substrate SUB and the intermediate dielectric layer and connects to the lower surface of the source layer of the pull-up transistor PU2 in the second group of field effect transistors, so that the pull-up transistor PU2 in the second group of field effect transistors is electrically connected to the power supply terminal. The pull-down transistor PD2 in the first group of field effect transistors may be electrically connected to the ground terminal in a similar method, which will not be described in detail here. Then, a multi-layer back-end interconnection process and a passivation protection process may be performed.

According to an embodiment of the present disclosure, the above-mentioned manufacturing method further includes the following steps. The intermediate dielectric layer is etched from the top to form a first opening exposing the source layer of the pull-down transistor in the second group of field effect transistors and a second opening exposing the source layer of the transmission transistor in the first group of field effect transistors, where the spacing space between the first group of field effect transistors and the second group of field effect transistors partially overlaps with a projection of the first opening in the vertical direction, and the spacing space partially overlaps with a projection of the second opening in the vertical direction. The first opening and the second opening are filled with conductive materials, and the first opening and the second opening are sealed. Thus, a contact hole 127_11 formed based on the first opening and a contact hole 127_12 formed based on the second opening may be obtained.

The intermediate dielectric layer in the spacing space between the first group of field effect transistors and the second group of field effect transistors is etched from the bottom, so as to form a third opening 132_1 exposing the conductive material in the first opening and a fourth opening 132_2 exposing the conductive material in the second opening. The third opening 132_1 and the fourth opening 132_2 are filled with conductive materials, so as to form, in the intermediate dielectric layer, a source layer contact hole connected to the source layer of the pull-down transistor PD2 in the second group of field effect transistors to electrically connect the pull-down transistor PD2 in the second group of field effect transistors to a ground terminal, and form, in the intermediate dielectric layer, a source layer contact hole connected to the source layer of the transmission transistor AC1 in the first group of field effect transistors to electrically connect the transmission transistor AC1 in the first group of field effect transistors to a bit line terminal. The source layer contact hole connected to the source layer of the pull-up transistor PU1 in the first group of field effect transistors in the embodiments of the present disclosure and the like may be manufactured in the same method, which will not be described in detail here.

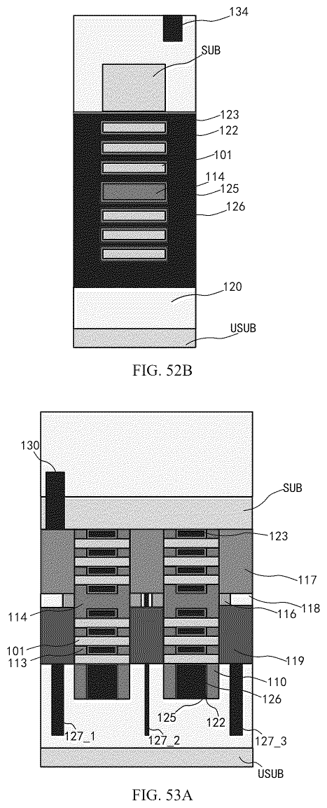

FIG. 52A is a cross-sectional view along the X-X′ axis in the process of manufacturing the staggered-layer cell. FIG. 52B is cross-sectional view along the Y4-Y4′ axis in the process of manufacturing the staggered-layer cell.

FIG. 53A is a cross-sectional view along the X-X′ axis in the process of manufacturing the staggered-layer cell. FIG. 53B is a cross-sectional view along the Y1-Y1′ axis in the process of manufacturing the staggered-layer cell. FIG. 53C is a cross-sectional view along the Y2-Y2′ axis in the process of manufacturing the staggered-layer cell. FIG. 53D is a cross-sectional view along the Y3-Y3′ axis in the process of manufacturing the staggered-layer cell. FIG. 54 is a cross-sectional view along the Y3-Y3′ axis of a three-dimensional stacked structure in which no first staggered-layer contact hole QB is arranged in some embodiments. By comparing FIG. 53D and FIG. 54, the structural difference between the staggered-layer cell with the first staggered-layer contact hole QB and the three-dimensional stacked structure without the first staggered-layer contact hole QB may be clearly seen.

According to an embodiment of the present disclosure, the pull-up transistor PD2 and the transmission transistor AC2 in the second group of field effect transistors are electrically connected to each other through a first common layer, and the pull-down transistor and the transmission transistor in the second group of field effect transistors are electrically connected to each other through the first common layer and a second common layer. The first staggered-layer contact hole QB and the second staggered-layer contact hole Q are formed in the intermediate dielectric layer to obtain the staggered-layer cell, which includes: etching the intermediate dielectric layer from top to form a fifth opening exposing each of the first common layer, the second common layer, and the gate stack of the pull transistor in the second group of field effect transistors; and filling the fifth opening with a conductive material that contacts with each of the first common layer, the second common layer and the gate stack of the pull transistor in the second group of field effect transistors, and sealing the fifth opening, so as to form the second staggered-layer contact hole Q.

According to an embodiment of the present disclosure, the pull-up transistor and the transmission transistor in the first group of field effect transistors are electrically connected to each other through a third common layer, and the pull-down transistor and the transmission transistor in the first group of field effect transistors are electrically connected to each other through the third common layer and a fourth common layer. The above-mentioned manufacturing method further includes the following steps. The intermediate dielectric layer is etched from the top along the surface of the intermediate dielectric layer, so as to form a sixth opening exposing the third common layer and the fourth common layer, where the spacing space between the first group of field effect transistors and the second group of field effect transistors partially overlaps with a projection of the sixth opening in the vertical direction. The sixth opening is filled with a conductive material, and the sixth opening is sealed.

The first staggered-layer contact hole and the second staggered-layer contact hole are formed in the intermediate dielectric layer to obtain the staggered-layer cell, which further includes: etching the intermediate dielectric layer from the bottom along the surface of the intermediate dielectric layer to form a seventh opening that exposes both the gate stack of the pull transistor in the second group of field effect transistors and at least one of the third common layer and the fourth common layer; and filling the seventh opening with a conductive material, and sealing the seventh opening, so as to form the first staggered-layer contact hole QB. On this basis, referring to FIG. 53C, it may be seen that the left conductive material in FIG. 53C corresponds to the gate structure of the transmission transistor AC1 in the first group of field effect transistors, and this gate structure is electrically connected to the word line. The right conductive material in FIG. 53C corresponds to the gate structure of the pull transistor in the second group of field effect transistors, and the gate structure is connected to the second staggered-layer contact hole Q. In addition, the conductive material filled in the opening 134 forms a contact hole electrically connected to a first bit line terminal, the conductive material filled in the opening 133_1 forms a contact hole electrically connected to the ground terminal, and the conductive material filled in the opening 133_2 forms a contact hole electrically connected to a second bit line terminal which complements the first bit line terminal. In addition, the left conductive layer 126 in FIG. 53C is led out from the back of the device, so as to be electrically connected to a word line terminal WL at the back of the device.

Based on this, according to the manufacturing method in the embodiments of the present disclosure, the second staggered-layer contact hole Q is connected to the gate stack of the pull transistor in the second group of field effect transistors and extends in the intermediate dielectric layer to be connected to the common layer of the first group of field effect transistors. In addition, the first staggered-layer contact hole QB is connected to the gate stack of the pull transistor in the first group of field effect transistors, extends in the intermediate dielectric layer to the lower surface of the substrate SUB and passes through the substrate SUB to be connected to the common layer of the second group of field effect transistors. As such, a local interconnection between the common layer of the second group of field effect transistors and the gate stack of the pull transistor in the first group of field effect transistors may be achieved through the back gate contact. Therefore, the first staggered-layer contact hole QB and the second staggered-layer contact hole Q, the storage bits of which are opposite to each other, form a staggered-layer structure with physically symmetrical upper and lower layers, so that it is possible to greatly reduce the in-plane area of an integrated circuit implemented based on the staggered-layer cell, while reducing the manufacturing difficulty to maintain a simple manufacturing process. In this way, the SRAM cell structure in which the storage bits of the back QB and the front Q are not limited to a same vertical plane may be achieved based on the staggered-layer cell in the present disclosure. Furthermore, an equivalent SRAM cell structure in which the storage bits of the back Q and the front QB are not limited to a same vertical plane may also be achieved based on the staggered-layer cell in the present disclosure.

The embodiments of the present disclosure are described above. However, these embodiments are for illustrative purposes only and are not intended to limit the scope of the present disclosure. Although the embodiments are described above separately, this does not mean that the techniques in the various embodiments cannot be combined advantageously. The scope of the present disclosure is defined in accordance with the appended claims and their equivalents. Without departing from the scope of the present disclosure, those skilled in the art may make various substitutions and modifications, which should all fall within the scope of the present disclosure.

What is claimed is:

1. A staggered-layer cell, comprising:
a first group of field effect transistors and a second group of field effect transistors on an upper surface of a substrate, wherein each of the first group of field effect transistors and the second group of field effect transistors is arranged in a first horizontal direction; and
an intermediate dielectric layer surrounding the substrate, the first group of field effect transistors and the second group of field effect transistors,
wherein each of the first group of field effect transistors and the second group of field effect transistors comprises a transmission transistor and stacked pull transistors, and the stacked pull transistors comprise a pull-down transistor and a pull-up transistor stacked in a vertical direction;
wherein each of the transmission transistor, the pull-down transistor and the pull-up transistor comprises: a channel layer; a source/drain layer connected to the channel layer on opposite sides of the channel layer in the first horizontal direction; and a gate stack that extends in a second horizontal direction intersecting the first horizontal direction and surrounds the channel layer; and the pull-down transistor, the pull-up transistor and the transmission transistor in a same group are coupled through a common layer; and
wherein a first staggered-layer contact hole connected to the gate stack of the pull transistor in the first group of field effect transistors, extends in the intermediate dielectric layer to a lower surface of the substrate and passes through the substrate to be connected to the common layer of the second group of field effect transistors, so as to form a staggered-layer structure with a second staggered-layer contact hole used to connect the gate stack of the pull transistor in the second group of field effect transistors and the common layer of the first group of field effect transistors, so that the first group of field effect transistors and the second group of field effect transistors are cross-coupled with each other.

2. The staggered-layer cell according to claim 1, wherein the first group of field effect transistors and the second group of field effect transistors are arranged along the second horizontal direction, and a spacing space is arranged between the first group of field effect transistors and the second group of field effect transistors;
wherein the first staggered-layer contact hole extends towards the spacing space from the gate stack of the pull transistor in the first group of field effect transistors to the lower surface of the substrate, and passes through the substrate to be connected to the common layer in the second group of field effect transistors; and
wherein the second staggered-layer contact hole extends towards the spacing space from the gate stack of the pull transistor in the second group of field effect transistors to a position above the substrate, so as to be connected to the common layer in the first group of field effect transistors.

3. The staggered-layer cell according to claim 2, wherein a source layer contact hole connected to an upper surface of the source layer of the transmission transistor in the first group of field effect transistors extends downwards in the spacing space to a surface of the intermediate dielectric layer, so as to electrically connect the transmission transistor in the first group of field effect transistors to a bit line terminal.

4. The staggered-layer cell according to claim 2,
wherein a source layer contact hole connected to a lower surface of the source layer of the pull-up transistor in the second group of field effect transistors passes through the substrate from the upper surface of the substrate and extends downwards to a surface of the intermediate dielectric layer, so as to electrically connect the pull-up transistor in the second group of field effect transistors to a power supply terminal; and
wherein a source layer contact hole connected to an upper surface of the source layer of the pull-down transistor in the second group of field effect transistors extends downwards in the spacing space to the surface of the intermediate dielectric layer, so as to electrically connect the pull-down transistor in the second group of field effect transistors to a ground terminal.

5. A method of manufacturing a staggered-layer cell, comprising:
forming a first group of field effect transistors and a second group of field effect transistors spaced apart from the first group of field effect transistors on an upper surface of a substrate, wherein each of the first group of field effect transistors and the second group of field effect transistors is arranged in a first horizontal direction, each of the first group of field effect transistors and the second group of field effect transistors comprises a transmission transistor and stacked pull transistors, and the stacked pull transistors comprise a pull-down transistor and a pull-up transistor stacked in a vertical direction; each of the transmission transistor, the pull-down transistor and the pull-up transistor comprises: a channel layer, a source/drain layer connected to the channel layer on opposite sides of the channel layer in the first horizontal direction, and a gate stack that extends in a second horizontal direction intersecting the first horizontal direction and surrounds the channel layer; and the pull-down transistor, the pull-up transistor and the transmission transistor in a same group are coupled through a common layer;
forming an intermediate dielectric layer surrounding the first group of field effect transistors, the second group of field effect transistors and the substrate; and
forming a first staggered-layer contact hole and a second staggered-layer contact hole in the intermediate dielectric layer to obtain the staggered-layer cell, wherein the second staggered-layer contact hole is connected to both the gate stack of the pull transistor in the second group of field effect transistors and the common layer of the first group of field effect transistors; the first staggered-layer contact hole is connected to the gate stack of the pull transistor in the first group of field effect transistors, extends in the intermediate dielectric layer to a lower surface of the substrate and passes through the substrate to be connected to the common layer of the second group of field effect transistors, so as to form a staggered-layer structure with the second staggered-layer contact hole, so that the first group of field effect transistors and the second group of field effect transistors are cross-coupled with each other.

6. The method according to claim 5, wherein the intermediate dielectric layer surrounds the first group of field effect transistors and the second group of field effect transistors; and
wherein the method further comprises:
etching the intermediate dielectric layer from top to form a first opening exposing the source layer of the pull-down transistor in the second group of field effect transistors and a second opening exposing the source layer of the transmission transistor in the first group of field effect transistors, wherein a spacing space between the first group of field effect transistors and the second group of field effect transistors partially overlaps with a projection of the first opening in the vertical direction, and the spacing space partially overlaps with a projection of the second opening in the vertical direction;
filling each of the first opening and the second opening with a conductive material, and sealing the first opening and the second opening;
etching the intermediate dielectric layer in the spacing space between the first group of field effect transistors and the second group of field effect transistors from bottom, so as to form a third opening exposing the conductive material in the first opening and a fourth opening exposing the conductive material in the second opening; and
filling each of the third opening and the fourth opening with a conductive material, so as to form, in the intermediate dielectric layer, a source layer contact hole connected to the source layer of the pull-down transistor in the second group of field effect transistors to electrically connect the pull-down transistor in the second group of field effect transistors to a ground terminal, and form, in the intermediate dielectric layer, a source layer contact hole connected to the source layer of the transmission transistor in the first group of field effect transistors to electrically connect the transmission transistor in the first group of field effect transistors to a bit line terminal.

7. The method according to claim 5, wherein the pull-up transistor and the transmission transistor in the second group of field effect transistors are electrically connected to each other through a first common layer, and the pull-down transistor and the transmission transistor in the second group of field effect transistors are electrically connected to each other through the first common layer and a second common layer; and
wherein the forming a first staggered-layer contact hole and a second staggered-layer contact hole in the intermediate dielectric layer to obtain the staggered-layer cell comprises:
etching the intermediate dielectric layer from top to form a fifth opening exposing each of the first common layer, the second common layer, and the gate stack of the pull transistor in the second group of field effect transistors; and
filling the fifth opening with a conductive material that contacts each of the first common layer, the second common layer and the gate stack of the pull transistor in the second group of field effect transistors, and sealing the fifth opening, so as to form the second staggered-layer contact hole.

8. The method according to claim 7, wherein the pull-up transistor and the transmission transistor in the first group of field effect transistors are electrically connected to each other through a third common layer, and the pull-down transistor and the transmission transistor in the first group of field effect transistors are electrically connected to each other through the third common layer and a fourth common layer; and
wherein the method further comprises:
etching the intermediate dielectric layer along a surface of the intermediate dielectric layer from top to form a sixth opening exposing the third common layer and the fourth common layer, wherein a spacing space between the first group of field effect transistors and the second group of field effect transistors partially overlaps with a projection of the sixth opening in the vertical direction; and
filling the sixth opening with a conductive material, and sealing the sixth opening; and
wherein the forming a first staggered-layer contact hole and a second staggered-layer contact hole in the intermediate dielectric layer to obtain the staggered-layer cell further comprises:
etching the intermediate dielectric layer along the surface of the intermediate dielectric layer from bottom to form a seventh opening exposing both the gate stack of the pull transistor in the second group of field effect transistors and at least one of the third common layer and the fourth common layer; and
filling the seventh opening with a conductive material, and sealing the seventh opening, so as to form the first staggered-layer contact hole.

9. The method according to claim 5, further comprising:
etching the substrate and the intermediate dielectric layer from bottom according to a position where the source layer of the pull-up transistor in the second group of field effect transistors is located, so as to form a source layer contact hole passing through the substrate and the intermediate dielectric layer to be connected to a lower surface of the source layer of the pull-up transistor in the second group of field effect transistors, so that the pull-up transistor in the second group of field effect transistors is electrically connected to a power supply terminal.

10. The method according to claim 5, wherein each of the first group of field effect transistors and the second group of field effect transistors further comprises a lower fin formed by etching the substrate; and a remaining portion of the substrate after etching is connected between the lower fin of the first group of field effect transistors and the lower fin of the second group of field effect transistors; and
wherein the forming an intermediate dielectric layer surrounding the first group of field effect transistors, the second group of field effect transistors and the substrate comprises:
etching the remaining portion of the substrate from bottom until a lower surface of the lower fin of the first group of field effect transistors and a lower surface of the lower fin of the second group of field effect transistors are exposed; and
depositing a dielectric material on each of the lower surface of the lower fin of the first group of field effect transistors and the lower surface of the lower fin of the second group of field effect transistors, so as to obtain the intermediate dielectric layer.
